(19) United States
(12) Patent Application Publication
(10) Pub. No.: US 2025/0183072 A1
(43) Pub. Date: Jun. 5, 2025

(54) SUBSTRATE PROCESSING DEVICE AND SUBSTRATE PROCESSING METHOD

(71) Applicant: TOKYO ELECTRON LIMITED, Tokyo (JP)

(72) Inventor: Daisuke MORISAWA, Yamanashi (JP)

(21) Appl. No.: 18/844,244

(22) PCT Filed: Mar. 1, 2023
(86) PCT No.: PCT/JP2023/007645

§ 371 Date: Sep. 5, 2024

(30) Foreign Application Priority Data
Mar. 15, 2022 (JP) 2022-040617

(51) Int. Cl. H01L 21/67; H01L 21/66

(52) U.S. Cl. CPC H01L 21/67253; H01L 21/67167; H01L 21/67276; H01L 22/12

(57) ABSTRACT

A substrate processing device of the present disclosure is provided with: a plurality of processing modules, each of which is provided with a processing vessel for storing a substrate and performing the same type of processing and each of which performs conditioning on the interior of the processing vessel; a transport mechanism for transporting the substrates to each of the plurality of processing modules; and a control unit for determining, from among the plurality of processing modules, a processing module to which to transport the substrates, such determination made on the basis of the run time for the conditioning, the processing time per substrate in the processing modules, and a parameter corresponding to the cumulative number of substrates processed after the conditioning with respect to each of the processing modules.

### TECHNICAL FIELD

The present disclosure relates to a substrate processing apparatus and a substrate processing method.

### BACKGROUND

In a substrate processing apparatus used for manufacturing semiconductor devices, a semiconductor wafer (hereinafter, referred to as “wafer”) is stored in a processing chamber, and is subjected to processing such as film formation or the like. Conditioning may be performed to adjust an internal environment of the processing chamber after a predetermined number of wafers are processed. Patent Document 1 discloses a substrate processing apparatus (substrate processing system) including four processing modules, each having a processing chamber, for performing the same processing. In the substrate processing apparatus, the substrate is transferred based on a predetermined rule so that the timing of conditioning in each processing module does not overlap.

### PRIOR ART DOCUMENTS

### Patent Documents

Patent Document 1: Japanese Laid-open Patent Publication No. 2015-35530

### SUMMARY

### Problems to Be Resolved by the Invention

The present disclosure provides a technique capable of increasing substrate processing efficiency in a substrate processing apparatus including a plurality of processing modules for performing the same processing.

### Means for Solving the Problems

In accordance with an aspect of the present disclosure, there is provided A substrate processing apparatus comprising: a plurality of processing modules, each of which includes a processing chamber for storing a substrate and performing same processing and each of which performs conditioning in the processing chamber; a transfer mechanism configured to transfer the substrate to each of the plurality of processing modules; and a controller configured to determine a processing module to which the substrate is transferred among the plurality of processing modules based on a parameter corresponding to a cumulative number of processed substrates after the conditioning with respect to each of the processing modules, an execution time of the conditioning, and a processing time per substrate of the processing modules.

### Effect of the Invention

In accordance with the present disclosure, the present disclosure can improve substrate processing efficiency in a substrate processing apparatus having a plurality of processing modules for performing the same processing.

### BRIEF DESCRIPTION OF THE DRAWINGS

FIG. 1 is a plan view of a substrate processing apparatus according to an embodiment of the present disclosure.

FIG. 2 is a longitudinal side view of a processing module included in the substrate processing apparatus.

FIG. 3 is a flowchart of a process for determining a rule to be applied.

FIG. 4 is a table showing a state of each processing module in test example 1.

FIG. 5 is a table showing a state of each processing module in comparative example 1.

FIG. 6 is a table showing a state of each processing module in test example 2.

FIG. 7 is a table showing a state of each processing module in comparative example 2.

FIG. 8 is a table showing a state of each processing module in test example 3.

FIG. 9 is a table showing a state of each processing module in comparative example 3.

FIG. 10 is a table showing a state of each processing module in test example 4.

FIG. 11 is a table showing a state of each processing module in comparative example 4.

FIG. 12 is a table showing a state of each processing module in test example 5.

FIG. 13 is a table showing a state of each processing module in comparative example 5.

FIG. 14 is a table showing the state of each processing module in test example 6.

FIG. 15 is a table showing the state of each processing module in comparative example 6.

FIG. 16 is a table showing the state of each processing module in test example 7.

FIG. 17 is a table showing the state of each processing module in comparative example 7.

FIG. 18 is a table showing the state of each processing module in test example 8.

FIG. 19 is a table showing the state of each processing module in comparative example 8.

### DETAILED DESCRIPTION

### (Overall Configuration of Substrate Processing Apparatus)

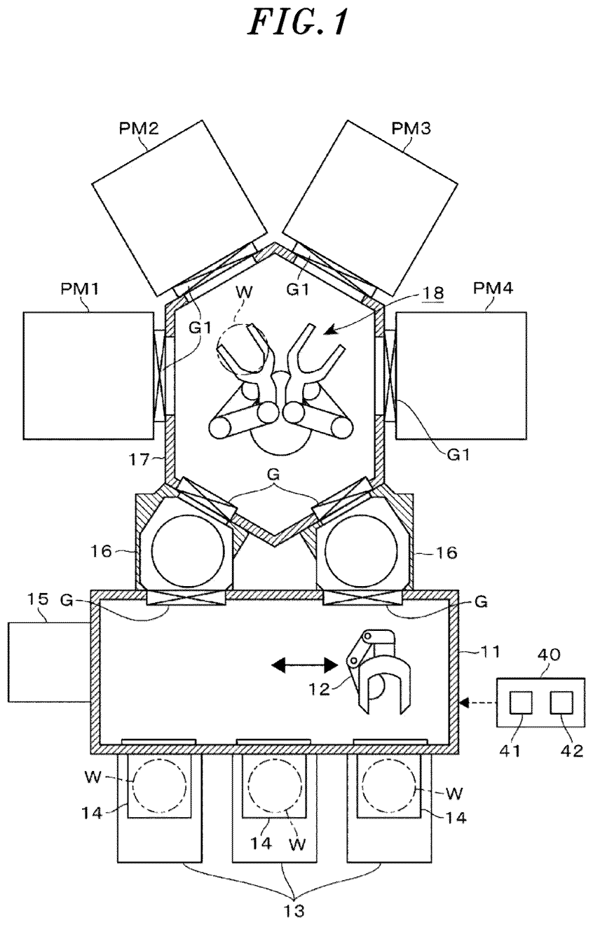

A substrate processing apparatus 1 including a substrate transfer apparatus according to an embodiment of the present disclosure will be described with reference to the plan view of FIG. 1. The substrate processing apparatus 1 is an apparatus for performing film formation on a wafer W, and includes a loader module 11, load-lock modules 16, a vacuum transfer module 17, and processing modules PM1 to PM4. The loader module 11, the load-lock modules 16, and the vacuum transfer module 17 are arranged in that order in a horizontal direction. In the following description of the substrate processing apparatus 1, in this arrangement, the side where the loader module 11 is located is set to a front side, and the side where the vacuum transfer module 17 is located is set to a rear side. Further, the right side and the left side in the description are set to the right side and the left side when viewed from the front side toward the rear side.

The loader module 11 includes a housing maintained at an atmospheric pressure, a transfer mechanism 12 for the wafer W that is disposed in the housing, and a plurality of load ports 13. The load ports 13 are arranged side by side in the left-right direction on the front side of the housing. A transfer chamber 14 for storing a wafer W, which is referred to as “front opening unified pod (FOUP),” is placed on each load port 13. Further, an alignment module 15 for adjusting the orientation or the eccentricity of the wafer W is disposed on the left side of the loader module 11 when viewed from the front side. The transfer mechanism 12 can transfer the wafer W between the transfer chamber 14 on each load port 13, the alignment module 15, and each load-lock module 16.

In this example, two load-lock modules 16 are arranged side by side in the left-right direction. The load-lock module 16 has a housing, and the housing is connected to the loader module 11 and the vacuum transfer module 17 via gate valves G disposed on the front and rear sides thereof. In a state where the gate valves G on the front and rear sides of the housing are closed, a pressure in the housing can be changed between an atmospheric pressure and a vacuum pressure. Further, a stage (not shown) on which the wafer W is placed is disposed in the housing, and the stage is configured to be able to transfer the wafer W to the transfer mechanism 12 and a transfer mechanism 18 to be described later, which access the load-lock module 16.

The vacuum transfer module 17 has a housing. The housing is evacuated through an exhaust port (not shown), and maintained at a vacuum atmosphere of a desired pressure. The processing modules PM1 to PM4 are connected to the housing of the vacuum transfer module 17 via gate valves G1. The gate valves G1 are closed except when the wafer W is transferred to or from the processing module PM. Further, the transfer mechanism 18 is disposed in the housing of the vacuum transfer module 17. The transfer mechanism 18 transfers the wafer W between the load-lock module 16 and each of the processing modules PM1 to PM4. The processing modules PM1 to PM4 have the same configuration, and may be simply referred to as “processing module PM” without numbers attached to PM when they are not distinguished from each other. Further, the term “processing module” may be omitted and simply referred to as “PM.”

### (Configuration of Controller)

The substrate processing apparatus 1 includes a controller 40, which is a computer, and the controller 40 includes a program 41 and a memory 42. The program 41 includes instructions (steps) so that the transfer of the wafer W between the modules constituting the substrate processing apparatus 1 and the processing and conditioning (to be described later) of the wafer W in the processing module PM can be performed. The controller 40 outputs control signals to individual components of the substrate processing apparatus 1 according to the program 41, and the operations of the individual components are controlled by the control signals, so that the transfer of the wafer W in the apparatus to be described later, and the processing and conditioning of the wafer W in the processing module PM are performed. Specifically, the supply of each gas into the processing chamber 21 for film formation, cleaning, and the conditioning in the processing module PM, the transfer of the wafer W by the transfer mechanisms 12 and 18, the opening/closing of the gate valves G and G1, and the switching of the pressure in the load-lock modules 16 are controlled by the control signals. The transfer of the wafer W is controlled to be performed according to rules to be described later.

Specifically, the program 41 is configured to perform calculation, determination, and counting of the cumulative processed number of wafers (to be described later) required for the transfer according to the rules. The program 41 is stored in a storage medium, such as a compact disc, a hard disk, a memory card, or a DVD, and is installed in the controller 40.

In the memory 42, parameters required for the transfer of the wafer W are stored. For example, parameters such as a processing time and a conditioning execution time per wafer W required for calculating an integer value n to be described later, a cumulative processed number N of a conditioning trigger, and the like are stored in the memory 42.

### (Transfer Path of Wafer W)

The following is description of the transfer path of the wafer W in the substrate processing apparatus 1. First, the wafer W is transferred in the order of the transfer chamber 14→the loader module 11→the alignment module 15→the load-lock module 16→the vacuum transfer module 17. Then, the wafer W is transferred to one of the processing modules PM1 to PM4 and subjected to film formation. Then, the wafer W is transferred in the order of the vacuum transfer module 17→the load-lock module 16→the loader module 11, and then returned to the transfer chamber 14. The pressure in the housing of the load-lock module 16 can be switched from an atmospheric pressure to a vacuum pressure when the wafer W is transferred to the vacuum transfer module 17, and from a vacuum pressure to an atmospheric pressure when the wafer W is transferred to the loader module 11. The wafer W is unloaded from the transfer chamber 14 and processed on a lot basis. In other words, after one lot is transferred from the transfer chamber 14 to each processing module PM and subjected to processing, another lot is transferred from the transfer chamber 14 to each processing module PM and subjected to processing.

### (Overview of Processing Module PM)

The processing modules PM1 to PM4 perform the same processing on the wafer W. Specifically, the same type of film is formed to have the same film thickness on the surface of the wafer W under the same processing conditions. Therefore, the processing time per wafer W is the same in the processing modules PM1 to PM4.

Further, in the processing modules PM1 to PM4, the conditioning is performed as described above. The conditioning is an operation performed in a state where the wafer W is not stored in the processing chamber 21 in order to adjust the environment in the processing chamber 21 constituting the processing modules PM1 to PM4. More specifically, the conditioning in this example includes cleaning performed by supplying a cleaning gas into the processing chamber 21, and pre-coating performed by supplying a film forming gas into the processing chamber 21 to cover individual components in the processing chamber 21 with a thin film. The conditioning is performed in the order of cleaning and pre-coating.

By performing the film formation on the wafer W, a film is also formed on the inner wall of the processing chamber 21 and the structures in the processing chamber 21. If the film formed on the inner wall and the structures in the processing chamber 21 becomes too thick due to repeated film formation, peeling may occur and particles may be adhered to the wafer W. By performing cleaning, the generation of particles is suppressed. In addition, by performing pre-coating, the environment in which the wafers W are performed can become uniform, which makes it possible to improve the uniformity of processing between the wafers W. Similarly to the film formation, the above-described conditioning is performed in the processing modules PM1 to PM4. Therefore, the time required for the conditioning is the same in the processing modules PM1 to PM4. Hereinafter, the time required for conditioning will be described as a conditioning execution time.

### (Configuration of Processing Module PM)

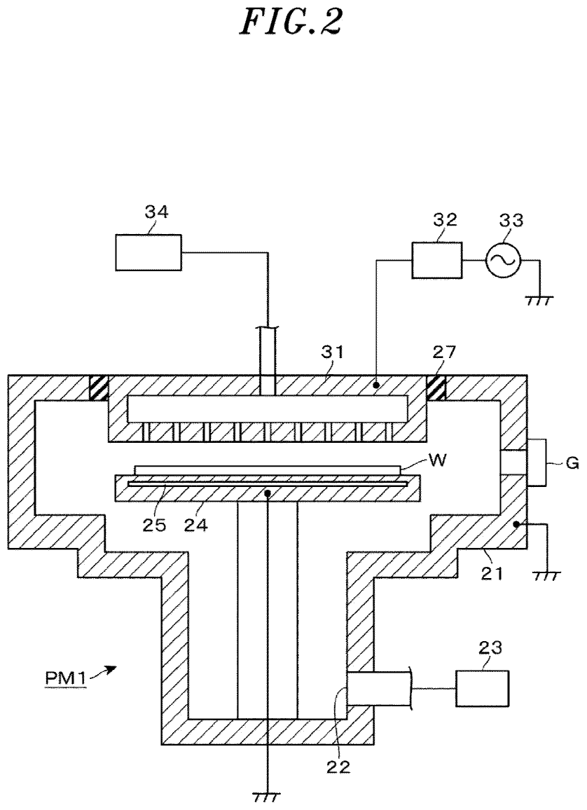

As described above, the processing modules PM1 to PM4 have the same configuration, and the configuration of the processing module PM1 will be representatively described with reference to the longitudinal side view of FIG. 2. In this example, in the processing module PM1, a film is formed on the wafer W by plasma chemical vapor deposition (CVD). As described above, the processing module PM1 includes a processing chamber 21 that is made of metal and is grounded. A transfer port for the wafer W on the sidewall of the processing chamber 21 is opened and closed by the above-described gate valve G1. An exhaust port 22 is opened at the processing chamber 21. The processing chamber 21 is evacuated through the exhaust port 22 by an exhaust mechanism 23 including a vacuum pump or the like, so that the processing chamber 21 is maintained at a vacuum atmosphere of a desired pressure.

A stage 24 for placing the wafer W is disposed in the processing chamber 21, and the wafer W is transferred between the stage 24 and the above-described transfer mechanism 18 by lift pins (not shown) configured to be raised and lowered on the stage 24. The stage 24 is configured as a grounded electrode for plasma generation. A heater 25 is embedded in the stage 24, and heats the wafer W to a desired temperature during the film formation.

A gas shower head 31 is disposed at a ceiling portion of the processing chamber 21 via an insulating member 27. A radio frequency (RF) power supply 33 is connected to the gas shower head 31 via a matching device 32. A gas supply mechanism 34 is connected to the gas shower head 31. The gas supply mechanism 34 can individually supply a film forming gas and a cleaning gas to the gas shower head 31, and the gas supplied to the gas shower head 31 is discharged toward the stage 24. The gas shower head 31 constitutes a parallel plate electrode together with the above-described stage 24, and the gas discharged from the gas shower head 31 onto the stage 24 is turned into plasma when the RF power supply 33 is turned on.

The wafer W is placed on the stage 24, and the film forming gas is discharged from the gas shower head 31 and turned into plasma, thereby forming a film on the surface of the wafer W by CVD. The cleaning and the pre-coating are performed by turning the cleaning gas and the film forming gas discharged from the gas shower head 31 into plasma. The pre-coating is also performed by CVD. As described above, the conditioning is performed in a state where the wafer W is not loaded into the processing chamber 21, so that the wafer W is not placed on the stage 24 when the cleaning and the pre-coating are performed.

### (Overview of Transfer Control of Present Disclosure)

The conditioning includes the cleaning as described above, and the cleaning is performed to prevent the thickness of the film formed on individual components in the processing chamber 21 from reaching a film thickness that may cause generation of particles. Therefore, after the conditioning is performed, a cumulative processed number of wafers W until next conditioning is performed is set. The set value of the cumulative processed number of wafers W until the next conditioning is performed is set to N. In other words, in the processing module PM in which the conditioning has been performed, the timing of conditioning is controlled such that next conditioning is performed after N-number of wafers W are processed after the conditioning. The N is a positive integer. When film formation is performed on the wafer W, a film is also formed on individual components in the processing chamber 21 with a film thickness corresponding to the film thickness of the film formed on the wafer W. Therefore, the set value N is a parameter that can be set depending on the film thickness of the film formed on the wafer W. In the following description, the set value N will be referred to as the cumulative processed number N of a C (conditioning) trigger. When it is simply referred to the cumulative number of processed wafers, it indicates the cumulative processed number of wafers W after previous conditioning is completed.

In the above-described Patent Document 1, in an apparatus having the same configuration as that of the substrate processing apparatus 1, a cycle in which the conditioning is sequentially performed in the processing modules PM1 to PM4 is formed by transferring the wafer W according to predetermined rules (first to third rules 1′ to 3′ to be described below). When the relationship of the following Eq. (1) is satisfied, in the same cycle and between consecutive cycles, after the conditioning is completed in one processing module PM, the conditioning is immediately started in a next processing module PM. In this state, the wafer W is processed in three processing modules PM where the conditioning is not being performed. Accordingly, the wafer W can be efficiently processed. In Eq. (1), (the number of processing modules PM−1) is three because the apparatus includes four processing modules PM. In the following description, the transfer of the wafer W according to the rules described in Patent Document 1 is referred to as “transfer of comparative example.”

Execution time of conditioning of processing module PM=(cumulative processed number N of C trigger/processing time of (number of processing modules PM−1)wafers) Eq. (1)

Due to miniaturization of semiconductor devices, the film formed on the wafers W is becoming thinner. Accordingly, there is a tendency in which a larger value is set for the cumulative processed number N of the conditioning trigger, and the following inequality (1) may be satisfied. If the transfer of the comparative example is performed when the relationship of inequality (1) is satisfied, a section in which the conditioning is not performed in any processing module PM is formed during the cycle, and only three processing modules PM are used in that section to process the wafer W. In other words, the wafer W is not transferred to the processing module PM in which the wafer W can be processed.

Execution time of conditioning of processing module PM<(cumulative processed number N of C trigger/processing time of (number of processing modules PM−1))wafers Inequality (1)

Although the above state can be avoided by setting the cumulative processed number N of the C trigger to a value lower than a settable upper limit value to satisfy the relationship of Eq. 1, it is not desirable to increase the frequency of conditioning. Under these circumstances, there is a demand for a technique for improving the processing efficiency of the apparatus by effectively utilizing each processing module PM. The transfer of the comparative example will be described in detail later, and will be compared with the transfer of the test example of the present disclosure.

In the substrate processing apparatus 1 of the present disclosure, the transfer control is performed to meet such a demand. In other words, a cycle in which the conditioning is sequentially performed is formed, and the transfer control is performed such that the wafer W can be transferred to all four processing modules PM and processed when it is possible to process the wafer W in all four processing modules PM during this cycle. Hereinafter, the transfer of the test example of the present disclosure will be described. In the transfer of the test example, the processing module PM to which the wafer W is transferred is determined based on the cumulative processed number of wafers W after the conditioning for each processing module PM, the conditioning execution time in the processing module PM, and the processing time per wafer W in the processing module PM.

More specifically, the conditioning execution time is divided by the processing time per wafer W, and an integer value is obtained by rounding off decimal parts of the obtained value that are not 0. If the integer value is expressed as “n,” the transfer control is performed based on n. Since it is calculated as described above, the unit of n is “sheet.” A specific example of n will be described. If the conditioning execution time is 720 minutes and the processing time per wafer W in the processing module PM is 3 minutes, 720 is divided by 3 and 240 is obtained. Since the decimal part of 240 is 0, no rounding off is performed, and n is 240. If it is 240.1, it is rounded off and n becomes 241.

The processing time per wafer W does not only indicate the time required to supply a gas to the wafer W, but also indicates time that is preset to include time required from when the wafer W is loaded into the processing chamber 21 until gas supply is started and time required to unload the wafer W from the processing chamber 21 after the gas supply is completed. Therefore, the processing time per wafer W is the same as the time from when one wafer W is placed on the stage 24 to be processed until a next wafer W is placed on the stage 24 to be processed in the case of sequentially transferring the wafers W to one processing module PM and processing them. It is assumed in the transfer of the test example that the processing time per wafer W is controlled to the preset time.

### (Rules for Transfer of Test Example)

In the substrate processing apparatus 1, if the conditioning is being performed in any one processing module PM among the processing modules PM1 to PM4, the wafer W is transferred to the processing modules PM in which the conditioning is not being performed. If the conditioning is not being performed in any of the processing modules PM1 to PM4, the wafer W is transferred according to the following first to fourth roles that are preset rules.

### First Rule

If the difference in the cumulative number of processed wafers in the processing modules PM that are first and fourth in the cumulative processed number in descending order is less than (n×3), the wafer W is transferred using the processing modules PM that are the first and fourth in the cumulative processed number in descending order.

### Second Rule

If the difference in the cumulative number of processed wafers in the processing modules PM that are first and third in the cumulative number of processed wafers in descending order is less than (n×2), the wafer W is processed using the processing modules PM that are the first, second, and fourth in the cumulative number of processed wafers in descending order.

### Third Rule

If the difference in the cumulative number of processed wafers in the processing modules PM that are first and second in the cumulative number of processed wafers in descending order is (n) or more, the wafer W is processed using all the processing modules PM.

### Fourth Rule

If none of the first, second, and third rules are applied, the wafer W is processed using the processing modules PM that are the first, third, and fourth in the cumulative number of processed wafers in descending order.

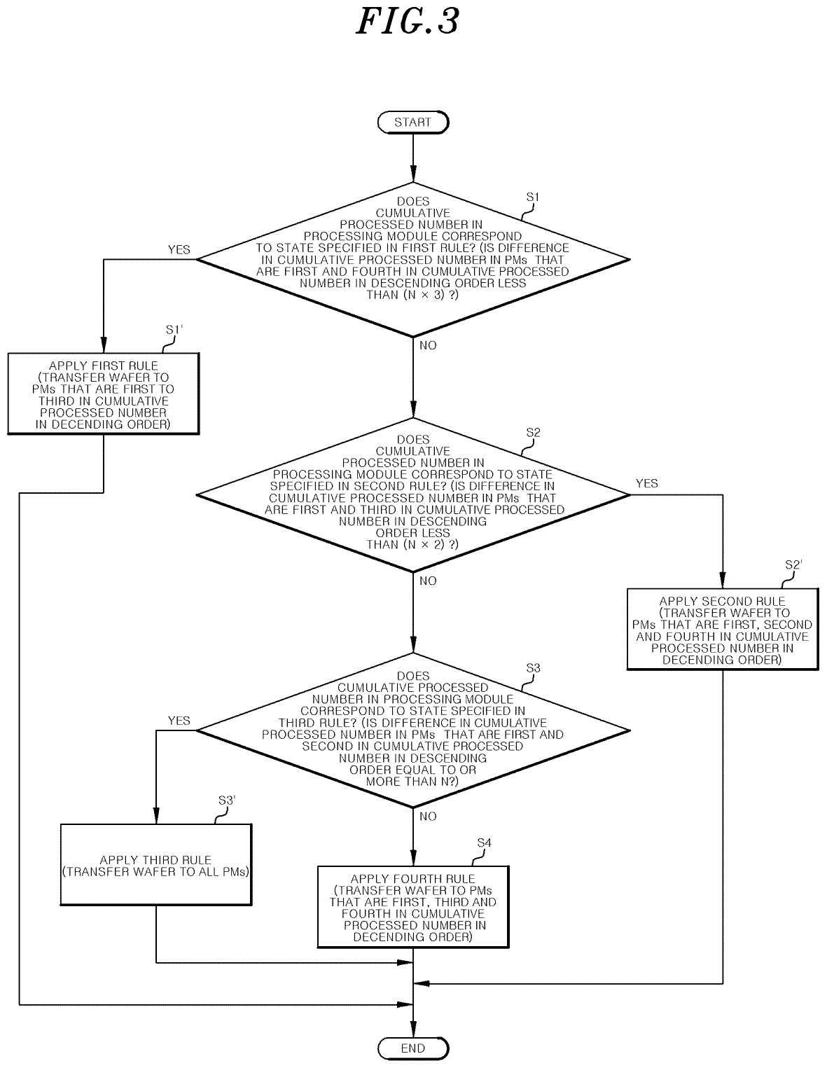

The first to fourth rules are applied in ascending order of numbers, that is, in the order of the first rule, the second rule, the third rule, and the fourth rule. Therefore, the above-described controller 40 executes the determination flow shown in FIG. 3. Specifically, in the determination flow, the wafer W is transferred to the processing module PM, and it is first determined whether or not the cumulative number of processed wafers in the processing module PM corresponds to the state specified in the first rule (step S1). If it is determined that it corresponds to the state specified in the first rule, the first rule is applied, and the processing module PM as a destination follows the first rule (step S1′).

If it is determined that it does not correspond to the state specified in the first rule, it is determined whether or not it corresponds to the state specified in the second rule (step S2). If it is determined that it corresponds to the state specified in the second rule, the second rule is applied, and the processing module PM as a destination follows the second rule (step S2′). If it is determined that it does not correspond to the state specified in the second rule, it is determined whether or not it corresponds to the state specified in the third rule (step S3). If it is determined that it corresponds to the state specified in the third rule, the third rule is applied, and the processing module PM as a destination follows the third rule (step S3′). If it is determined that it does not correspond to the state specified in the third rule, the fourth rule is applied, and the processing module PM as a destination follows the fourth rule (step S4).

In this manner, the wafers W are repeatedly transferred sequentially one by one to the processing modules PM determined as destinations according to the first to fourth rules. Specifically, when the third rule is applied, the wafers W are repeatedly transferred in the order of PM numbers, for example, in the order of PM1, PM2, PM3, PM4, PM1, PM2, . . . . Further, as will be described in the following principle (3), when there is a PM in which the conditioning has just been performed, the wafers are transferred from the PM first.

When the above rules are applied, the cumulative number of processed wafers may be the same in the plurality of PMs. In that case, the order is assigned according to preset rules. For example, the rules are applied on the assumption that among PM1 to PM4 having the same cumulative number of processed wafers, a PM having a lower number has a lower order in the cumulative number of processed wafers in descending order. Specifically, when the first rule is applied, the cumulative number of processed wafers may be the same in PM1 to PM4 and, thus, the first and fourth cumulative number of processed wafers may be the same. In this case, among PM1 to PM4 having the same cumulative number of processed wafers, it is considered that a PM having a lower number has a lower order in the cumulative number of processed wafers in descending order. In other words, PM1, PM2, PM3, and PM4 that are first, second, third, and fourth in the cumulative number of processed wafers in descending order, respectively.

In brief, the first to fourth rules are determined such that a difference in the cumulative number of processed wafers between PM1 to PM4 is n or more as described above. Due to such a difference, a cycle in which the conditioning is sequentially performed in PM1 to PM4 can be executed, as will be specifically described later in simulation. Even if a section in which no conditioning is required in any PM is formed in the cycle due to a relatively large cumulative number of processed wafers N of the C trigger, the transfer is performed in that section according to the third rule. Therefore, a state in which the wafer W is not transferred to the processing module PM capable of processing the wafer W is avoided. Since the wafer W is transferred according to the first to fourth rules until the cycle is formed and only the third rule is used during the execution of the cycle, the PM in which the conditioning is performed is shifted so that the difference in the cumulative number of processed wafers between the PMs in which the conditioning is not performed can be maintained to be n or more in the cycle. Further, the wafers W are processed using at least three PMs according to the first to fourth rules until the cycle in which the PMs in which the conditioning is sequentially performed is shifted is formed. In other words, there is only one PM to which the wafer W is not transferred before the formation of the cycle, and the decrease in the processing efficiency of the apparatus is prevented.

The wafer W is transferred in the substrate processing apparatus 1 according to the following principles (1) and (2), for example.
(1) The determination for applying the above rules and the conditioning in the processing module PM are started when the lot of the wafers W to be transferred to the processing module PM is switched.
(2) After the conditioning is completed, the PM in which the conditioning has just been completed is used.

According to the principle (2), if the conditioning has just been completed in any one of the processing modules PM as a plurality of transfer destinations, the wafer W is first transferred to the PM before it is transferred to the other PMs.

Further, according to the principle (1), the cumulative number of processed wafers in one of the processing modules PM has reached the cumulative number of processed wafers N of the C trigger while the wafers W included in one lot are being transferred to the processing module PM, but a wafer W that has not yet been transferred to the processing module PM exists in the one lot. In that case, the rules to be applied are not changed and the conditioning is not started. Therefore, after a number of wafers W that exceeds the cumulative number of processed wafers N of the C trigger are transferred to the processing module PM, the conditioning may be started in the processing module PM by switching a lot. However, in the simulation to be described below, it is assumed that the timing at which the cumulative number of processed wafers reaches the cumulative number of processed wafers N of the C trigger coincides with the timing at which the lot is switched, and the conditioning is started when the cumulative number of processed wafers reaches the cumulative number of processed wafers N of the C trigger. Although the number of wafers W included in one lot varies, if a lot including X wafers W (X being an integer) is continuously transferred to the substrate processing apparatus 1, the first to fourth rules are applied when the cumulative number of processed wafers of all PMs is a multiple of X. In that case, the conditioning is started when the cumulative number of processed wafers of all PMs is a multiple of X. Here, the cumulative number of processed wafers is the sum of the cumulative number of processed wafers of PM1 to PM4.

### (Rules for Transfer Method of Comparative Example)

Hereinafter, the results of simulations of the transfer method of the test example and the transfer method of the comparative example will be described, and the effects of the transfer of the test example will be described. To that end, the transfer method of the comparative example will be further described. In the simulation, the transfer method of the test example and the transfer method of the comparative example are different only in the transfer control rules. In other words, in the comparative example, the transfer is performed not according to the first to fourth rules but according to the following first′ to third′ rules.

### First′ Rule

When the cumulative number of processed wafers of the processing module PM that is third in the cumulative number of processed wafers in descending order is less than (N×3/6), the processing modules PMs that are the first to third in the cumulative number of processed wafers in descending order are used for processing.

### Second′ Rule

When the cumulative number of processed wafers of the processing module PM that is second in the cumulative number of processed wafers in descending order is less than (N×5/6), the processing modules PM that are the first to third in the cumulative number of processed wafers in descending order are used for processing.

### Third′ Rule

If neither the first′ rule nor the second′ rule is applied, the processing modules PM that are the first, third, and fourth in the cumulative number of processed wafers in descending order are used for processing.

The N in the first′ rule and the second′ rule is the above-described cumulative number of processed wafers N of the C trigger. The first′ to third′ rules are applied in the order of the first′ rule, the second′ rule, and the third′ rule. Further, similarly to the transfer method of the test example, in the transfer method of the comparative example, when the cumulative number of processed wafers is the same in the processing modules PM1 to PM4, the processing modules PM1 to PM3 serve as the transfer destination of the wafer W. As described above, in brief, the transfer method of the comparative example is performed such that all PMs are not used at the same time.

### (Preconditions of Simulation)

Hereinafter, the simulations on the transfer of the test example and the transfer of the comparative example will be described. In the simulations, the conditioning execution time and the processing time per wafer W in the processing module PM were set to 720 minutes and 3 minutes, respectively, that are the same as the above-described values. Therefore, n, which is calculated from such parameters and used in the rules of the test example, is 240 that is the same as the above-described value.

The cumulative number of processed wafers N of the C trigger varies depending on test examples. Accordingly, the relationship between the conditioning execution time and the processing time of (cumulative number of processed wafers N of C trigger/3) wafers W, which constitute the left side and the right side of inequality (1), respectively, was made to be different depending on the test examples, and was examined. Further, the cumulative number of processed wafers (initial state) of wafers W in PM1 to PM4 at the start of transfer was also made to be different depending on the test examples, and was examined. Similarly to the differences depending on the test examples, the cumulative number of processed wafers N of the C trigger and the initial state were made to be different depending on comparative examples, and was examined.

### Test Example 1

In test example 1, the cumulative number of processed wafers N of the C trigger was set to 1500. Therefore, the processing time of (the cumulative number of processed wafers N of the C trigger/3) wafers W is 1500 minutes, and the relationship of inequality (1) (the conditioning execution time<the processing time of (the cumulative number of processed wafers N of the C trigger N/3) wafers W) is satisfied. In test example 1, the difference between the left side and the right side of inequality (1) is relatively large, and the value of the right side is more than twice the value of the left side. Further, in the initial state of test example 1, the cumulative number of processed wafers in all the processing modules PM1 to PM4 is 0.

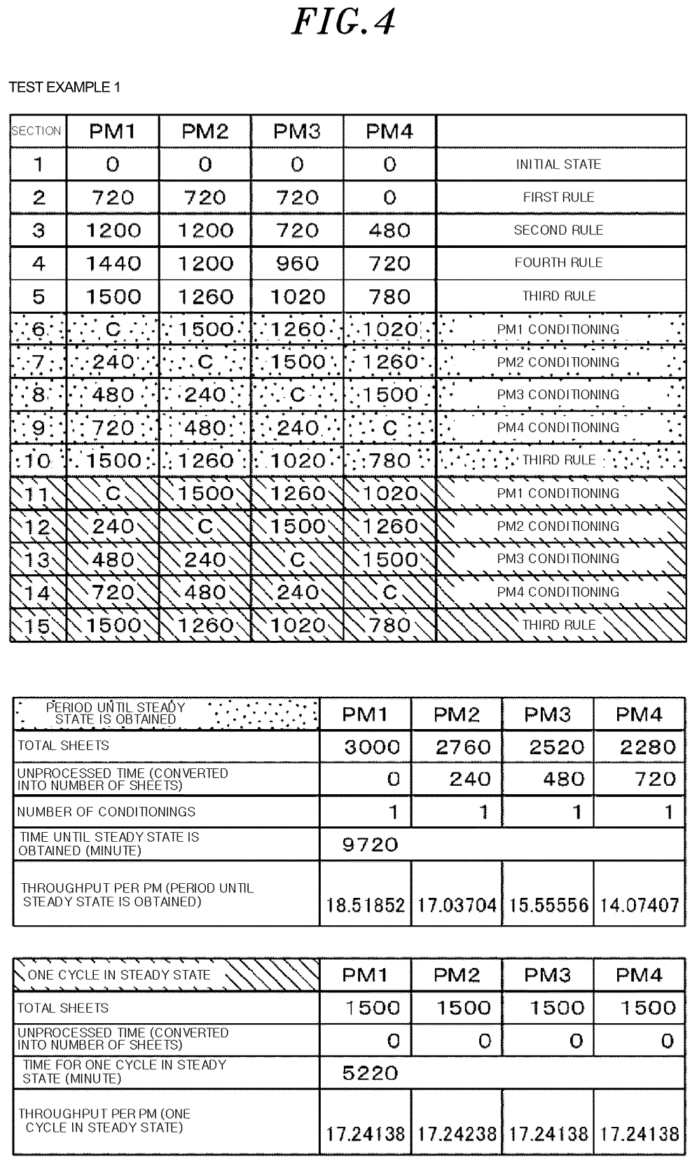

The table in the upper part of FIG. 4 shows the simulation results of test example 1, in which the period in which the transfer is performed is divided into multiple sections, and the state of each processing module PM in each section is shown. More specifically, the rows correspond to the sections, and the columns correspond to the processing modules PM. Although the sections are arranged downward in ascending order, the section number increases as the elapsed time from the start of transfer increases, and the section number changes when the rule to be applied or the processing module in which the conditioning is performed changes. In each processing module PM, the section in which the conditioning is being performed is expressed by “C” and the section in which the conditioning is not being performed is expressed by the cumulative number of processed wafers. The cumulative number of processed wafers shown in the table indicates a value obtained immediately before the end of each section. In the sections where the conditioning is not performed, the rules applied to the sections are displayed. Hereinafter, the table showing the state of the processing module PM is referred to as “transfer table.”

The states of the processing modules PM1 to PM4 and the rules to be applied will be described in the order of sections in test example 1.

Section 1 indicates an initial state, and the cumulative number of processed wafers of PM1 to PM4 is set to 0 as described above. In order to determine the rule to be applied from the initial state, the determination flow shown in FIG. 3 is executed. In this case, if the cumulative number of processed wafers is the same as described above, the descending order of the cumulative number of processed wafers corresponds to the PM number, so that the descending order is considered to be the order of PM1, PM2, PM3, and PM4. Although it is determined whether or not the scope of the first rule is applicable according to the determination flow, the difference in the cumulative number of processed wafers between PM1 that is first in the cumulative number of processed wafers in descending order and PM4 that is determined to be fourth in the cumulative number of processed wafers in descending order is 0, which is less than n×3=720. Since it is determined that the scope of the first rule is applicable, the application of the first rule is determined, and section 1 is ended.

In section 2, the wafers W are transferred to PM1 to PM3 that are determined to be first to third in the cumulative number of processed wafers in descending order according to the first rule. The difference in the cumulative number of processed wafers between PM1 that is first in the cumulative number of processed wafers in descending order and PM4 that is fourth in the cumulative number of processed wafers in descending order becomes n×3=720, and the scope of the first rule is not applicable.

In a state where the difference in the cumulative number of processed wafers is formed, the determination flow is executed. In this case, the cumulative number of processed wafers is the same in PM1 to PM3, so that the descending order of the cumulative number of processed wafers in PM1 to PM3 corresponds to the PM number. Hence, the descending order is considered to be the order of PM1, PM2, PM3, and PM4. First, it is determined by the determination flow that the scope of the first rule is not applicable. Then, it is determined whether or not the scope of the second rule is applicable. Since the difference in the cumulative number of processed wafers between PM1 that is first in the cumulative number of processed wafers in descending order and PM3 that is third in the cumulative number of processed wafers in descending order is 0, which is less than (n×2)=480 sheets, it is determined that the scope of the second rule is applicable. Thus, the rule to be applied is switched to the second rule, and section 2 is ended.

In section 3, the wafers W are transferred to PM1, PM2, and PM4 according to the second rule. The cumulative number of processed wafers in PM1, PM2, PM3, and PM4 are 1200, 1200, 720, and 480, respectively. In other words, the difference in the cumulative number of processed wafers between PM1 that is considered to be first in the cumulative number of processed wafers in descending order and PM3 that is considered to be third in the cumulative number of processed wafers in descending order becomes n×2=480, so that the scope of the second rule is not applicable.

In a state where such a difference in the cumulative number of processed wafers is formed, the determination flow is executed. In this case, the cumulative number of processed wafers in PM1 and PM2 are the same, so that the descending order of the cumulative number of processed wafers in PM1 and PM2 correspond to the PM numbers. Therefore, the descending order is the order of PM1, PM2, PM3, and PM4. Although it is first determined whether or not the scope of the first rule is applicable by the transfer flow, the difference in the cumulative number of processed wafers between PM1 that is first in descending order, which is 1200, and PM4 that is fourth in descending order, which is 480, is not less than n×3=720, so that it is determined that the scope of the first rule is not applicable. Since it is determined that the scope of the second rule is not applicable, whether or not the scope of the third rule is applicable is determined next. The difference between PM1 that is first in descending order and PM2 that is second in descending order is 0, which is not n(=240) or more, so that it is determined that the scope of the third rule is not applicable, and also determined that that the scope of the fourth rule is applicable. Accordingly, the rule to be applied is switched to the fourth rule, and section 3 is ended.

In section 4, the wafers W are transferred to PM1, PM3, and PM4 according to the fourth rule. The cumulative number of processed wafers in PM1, PM2, PM3, and PM4 are 1440, 1200, 960, and 720, respectively. In other words, the difference in the cumulative number of processed wafers between PM1 that is first in the cumulative number of processed wafers in descending order and PM2 that is second in the cumulative number of processed wafers in descending order is n(=240) or more, so that the scope of the third rule is applicable.

In a state where such a difference in the cumulative number of processed wafers is formed, the determination flow is executed to determine whether or not the scope of the first rule is applicable. Since, however, the difference between PM1 that is first in the cumulative number of processed wafers in descending order, which is 1440, and PM4 that is fourth in the cumulative number of processed wafers in descending order, which is 720, is not less than n×3=720, it is determined that the scope of the first rule is not applicable. Next, it is determined whether or not the scope of the second rule is applicable. Since, however, the difference between PM1 that is first in the cumulative number of processed wafers in descending order, which is 1440, and PM3 that is third in the cumulative number of processed wafers in descending order, which is 960, is not less than n×2=480, it is determined that the scope of the second rule is not applicable. Next, it is determined whether or not the scope of the third rule is applicable. Since it is determined that the scope the third rule is applicable, the rule to be applied rule is switched to the third rule, and section 4 is ended.

In section 5, the wafers W are transferred to PM1 to PM4 according to the third rule. The cumulative number of processed wafers in PM1, PM2, PM3, and PM4 are 1500, 1260, 1020, and 780, respectively. In other words, the cumulative number of processed wafers in PM1 reaches 1500 that is the cumulative number of processed wafers N of the C trigger, so that the conditioning is started and section 5 is ended.

In section 6, the wafers W are transferred to PM2 to PM4 where conditioning is not performed. The conditioning in PM1 is completed, and the cumulative number of processed wafers in PM2, PM3, and PM4 are 1500, 1260, and 1020, respectively. In other words, the cumulative number of processed wafers in PM2 reaches 1500 that is the cumulative number of processed wafers N of the C trigger, so that the conditioning is started and section 6 is ended.

In section 7, the wafers W are transferred to PM1, PM3, and PM4 where conditioning is not performed. The conditioning in PM2 is completed, and the cumulative number of processed wafers in PM1, PM3, and PM4 are 240, 1500, and 1260, respectively. In other words, the cumulative number of processed wafers in PM3 reaches 1500 that is the cumulative number of processed wafers N of the C trigger, so that the conditioning is started and section 7 is ended.

In section 8, the wafers W are transferred to PM1, PM2, and PM4 where conditioning is not performed. The conditioning in PM3 is completed, and the cumulative number of processed wafers in PM1, PM2, and PM4 are 480, 240, and 1500, respectively. In other words, the cumulative number of processed wafers in PM4 reaches 1500 that is the cumulative number of processed wafers N of the C trigger, so that the conditioning is started and section 8 is ended.

In section 9, the wafers W are transferred to PM1 to PM3 where conditioning is not performed. The conditioning in PM4 is completed, and the cumulative number of processed wafers in PM1, PM2, and PM3 are 720, 480, and 240, respectively. In a state where the conditioning is not performed in any PM, the determination flow is executed, and whether or not the scope of the first rule is applicable is determined first. Since the difference in the cumulative number of processed wafers between PM1 that is first in the cumulative number of processed wafers in descending order, which is 720, and PM4 that is fourth in the cumulative number of processed wafers in descending order, which is 0, is not less than n×3−720, it is determined that the scope of the first rule is not applicable.

Next, it is determined whether or not the scope of the second rule is applicable. Since the difference between PM1 that is first in the cumulative number of processed wafers in descending order, which is 720, and PM3 that is third in the cumulative number of processed wafers in descending order, which is 240, is not less than n×2=480, it is determined that the scope of the second rule is not applicable. Then, whether or not the scope of the third rule is applicable is determined. Since the difference between PM1 that is first in the cumulative number of processed wafers in descending order, which is 720, and PM2 that is second in the cumulative number of processed wafers in descending order, which is 480, is n(=240) or more, it is determined that the scope of the third rule is applicable. Hence, the third rule is applied, and section 9 is ended.

In section 10, the wafers W are transferred to PM1 to PM4 according to the third rule. The cumulative number of processed wafers in PM1, PM2, PM3, and PM4 are 1500, 1260, 1020, and 780, respectively. In other words, the cumulative number of processed wafers in PM1 reaches 1500 that is the cumulative number of processed wafers N of the conditioning trigger, so that the conditioning is started and section 10 is ended.

Similarly to section 6, in section 11, the conditioning is performed in PM1, and the difference in the cumulative number of processed wafers, which is the same as that in section 6, is formed between the processing modules PM2 to PM4 as shown in the transfer table. Therefore, in sections 11 to 15, the wafers W are transferred according to the rules that are the same as those applied to sections 6 to 10. Hence, the difference in the cumulative number of processed wafers, which is the same as that in sections 6 to 10, is formed between the processing modules PM, and the conditioning is performed in each processing module PM in the same order as that in sections 6 to 10.

If one cycle includes a section in which the transfer is performed only according to the third rule among the first to fourth rules and a plurality of other consecutive sections in which the conditioning is performed in the processing modules PM1 to PM4, the cycle is repeated after section 6. Sections 6 to 10 form a first cycle, and sections 11 to 15 form a second cycle. The state in which the cycle is repeated is set to a steady state, and a period until the end of the first cycle is set to “a period until the steady state is obtained.” Therefore, in test example 1, the period until the steady state is obtained is the period until section 10. In the transfer table, the sections forming the first cycle until the steady state is obtained are expressed by dots, and the sections forming the second cycle is expressed by diagonal lines.

Since the wafers W are transferred according to the first to fourth rules as described above, the transfer table shows that the section is shifted such that the difference of 240 sheets or more (i.e., n sheets or more) in the number of sheets between PMs in which the conditioning is not performed is maintained in the steady state. Specifically, as shown in the transfer table, immediately before the end of section 6, the cumulative number of processed wafers in three PMs in which the conditioning is not performed are 1020, 1260, and 1500. Thus, the difference of 240 sheets is formed. Immediately before the end of section 7, the cumulative number of processed wafers in the three PMs in which the conditioning is not performed are 240, 1260, and 1500, so that the difference of 240 sheets or more is formed. This is the same for section 8 and subsequent sections. Immediately before the end of section 10, the difference of 240 sheets is formed between the four processing modules PM in which the conditioning is not performed.

However, in one section, the difference in number of sheets between PMs varies, and there is timing at which the difference in the number of sheets becomes less than 240. Specifically, for example, immediately after the end of section 6, by transferring the wafer W to PM1 in which the conditioning has been completed at the start of section 7, the difference in the number of sheets becomes less than 240. Therefore, although it is described that the difference of n or more in the cumulative number of processed wafers between PMs in which the conditioning is not performed is maintained in the steady state, this does not indicate that the difference of n or more is constantly formed, and indicates that the transfer is performed such that timing at which the difference of n or more is formed exists in each section of the steady state as described above.

### (Summary of Test Example 1)

Tables in which various data obtained by the transfer of test example 1 is divided into data until the steady state is obtained and data in one cycle of the steady state are provided below the transfer table shown in FIG. 4. In the data, an unprocessed time (converted into the number of sheets) is the number of wafers W with respect to time in which the wafers W can be transferred because conditioning is not performed but are not transferred due to the transfer rules.

According to the data until the steady state is obtained, the total numbers of processed wafers W in PM1, PM2, PM3, and PM4 were 3000, 2760, 2520, and 2280, respectively. The unprocessed time (converted into the number of sheets) was 0, 240, 480, and 720 in PM1, PM2, PM3, and PM4, respectively. The number of conditionings was 1 in each of PM1 to PM4. In each processing module PM, the total number of wafers+the unprocessed time (converted into the number of sheets) was 3000, and the number of conditionings was 1. Therefore, the time required until the steady state was obtained was calculated as 3000 sheets×(processing time per wafer W=3 minutes)+execution time of one conditioning (720 minutes)=9720 minutes. The throughput per PM was calculated as the total number of wafers W until the steady state was obtained/the time (minutes) until the steady state was obtained×60 minutes, and was 18.51852, 17.03704, 15.55556, and 14.07407 in PM1, PM2, PM3, and PM4, respectively.

According to the data in one cycle in the steady state, the total number of wafers W processed in PM1, PM2, PM3, and PM4 was 1500. The unprocessed time (converted into the number of sheets) in PM1 to PM4 was 0. The time for one cycle in the steady state, which is (total number of wafers W+unprocessed time (converted into the number of sheets)) for any one processing module PM×processing time per wafer W+conditioning execution time during one cycle, was calculated as 1500 sheets×3 minutes/sheet+720 minutes=5220 minutes. The throughput per PM was calculated as total number of wafers W in one cycle/time for one cycle (minutes)×60 minutes, and was 17.24138, 17.24238, 17.24138, and 17.24138 in PM1, PM2, PM3, and PM4, respectively.

### Comparative Example 1

Similarly to test example 1, in comparative example 1, the cumulative number of processed wafers N of the C trigger was set to 1500, and the simulation was performed by starting the transfer in a state where the cumulative number of processed wafers was 0 in all the processing modules PM1 to PM4. Further, the steady state in the comparative example in the following description is different from the steady state in the test example in that a section in which the transfer according to the first′ rule may be included instead of a section in which the transfer is performed according to the third rule.

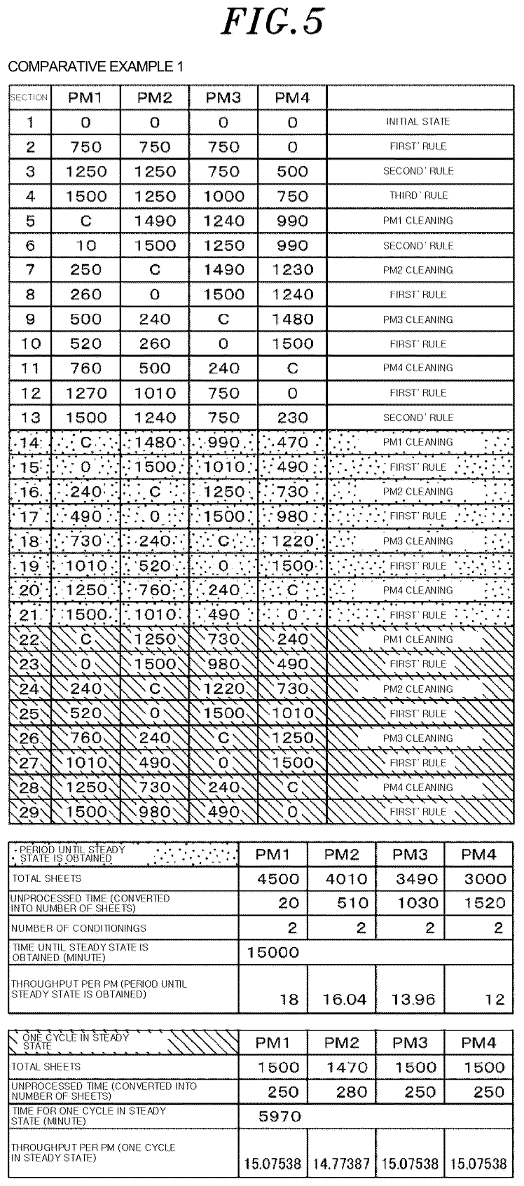

Similarly to FIG. 4 showing test example 1, FIG. 5 shows, as a transfer table and tables of various data, the results of simulation on the transfer of comparative example 1. As clearly can be seen from the transfer table of FIG. 5, in the steady state, there is a section in which the wafers W are transferred for a while to a PM in which the conditioning has been performed. Specifically, sections 14 to 16 in the transfer table will be described. The conditioning of PM1 is performed in section 14, and is completed in section 15. However, after section 14, the wafers W are transferred only to PM2 to PM4, and the transfer to PM1 is started by starting the conditioning of PM2 in section 16.

### Summary of Comparative Example 1

The data until the steady state is obtained will be described. The total number of wafers W processed in PM1, PM2, PM3, and PM4 were 4500, 4010, 3490, and 3000, respectively. The unprocessed time (converted into the number of sheets) was 20, 510, 1030, and 1520 in PM1, PM2, PM3, and PM4, respectively. The number of conditionings was two in each of PM1 to PM4. In each processing module PM, the total number of sheets+the unprocessed time (converted into the number of sheets) was 4520, and the number of conditionings was two. Therefore, the time required until the steady state was obtained was calculated as 4520 sheets×the processing time per wafer W (3 minutes)+time for executing conditioning twice (720 minutes×2)=150,000 minutes. The throughput per PM was calculated in the order described in test example 1, and was 18, 16.04, 13.96, and 12 in PM1, PM2, PM3, and PM4, respectively.

The data for one cycle in the steady state will be described. The total number of wafers W processed in PM1, PM2, PM3, and PM4 were 1500, 1470, 1500, and 1500, respectively. The unprocessed time (converted into the number of sheets) was 250, 280, 250, and 250 in PM1 to PM4, respectively. The time for one cycle in the steady state, which is (total number of wafers W+unprocessed time (converted into number of wafers)) for any one processing module PM×processing time per wafer W+conditioning execution time in one cycle, was calculated as 1750 sheets×3 minutes/sheet+720 minutes=5970 minutes. The throughput per PM was calculated in the order described in test example 1, and was 15.07538, 14.77387, 15.07538, and 15.07538 in PM1, PM2, PM3, and PM4, respectively.

### Comparison Between Test Example 1 and Comparative Example 1

In both test example 1 and comparative example 1, in the steady state, the conditioning was performed in PM1 to PM4 sequentially one by one. Further, in the steady state, a section in which the conditioning is not performed is formed in any PM. In comparative example 1, in this section, the wafer W is not immediately transferred to the PM after the conditioning is completed. On the other hand, in test example 1, in this section, the wafer W is transferred to each of PM1 to PM4 and processed. In other words, in test example 1, the time in which the PM stands by without processing the wafer W can be reduced.

The time required until the steady state was obtained was 9720 minutes in test example 1 and 15000 minutes in comparative example 1, which is shorter in test example 1. As described above, in the steady state, in test example 1, unlike comparative example 1, there is no case in which the wafer W cannot be transferred to the PM after the conditioning is completed, and the processing is performed in all PMs in which the conditioning is not performed as described above. Therefore, in consideration of increasing the processing efficiency of the apparatus, it is preferable to quickly obtain the steady state in test example 1. The steady state was obtained earlier in test example 1 than in comparative example 1, which was desirable.

The minimum throughput per PM until the steady state was obtained was 14.07407 in test example 1 and was 12 in comparative example 1, so that test example 1 was 117.3% on the assumption that comparative example 1 was 100%. The maximum throughput per PM until the steady state was obtained was 18.51852 in test example 1 and was 18 in comparative Example 1, so that test example 1 was 102.9% on the assumption that comparative example 1 was 100%. The throughput per PM in one cycle in the steady state was 17.24138 in test example 1 and was 15.07538 in comparative Example 1, so that test example 1 was 114.4% on the assumption that comparative example 1 was 100%. The throughput of each PM was higher in test example 1 in both the period until the steady state was obtained and the cycle in the steady state. Hence, it was confirmed that the processing efficiency of the apparatus was higher in test example 1.

### Test Example 2 and Comparative Example 2

In test example 2, simulation was performed under the same conditions as those in test example 1 except that the cumulative number of processed wafers in the initial state was not 0 in PM1 to PM4. Therefore, also in test example 2, the cumulative number of processed wafers N of the C trigger was 1500, and the relationship of inequality (1) (conditioning execution time<processing time of (cumulative number of processed wafers N of C trigger/3) wafers W) was satisfied. Specifically, the cumulative number of processed wafers in the initial state was set to 920, 1394, 140, and 723 in PM1, PM2, PM3, and PM4, respectively. In comparative example 2, simulation was performed under the same conditions as those in test example 2.

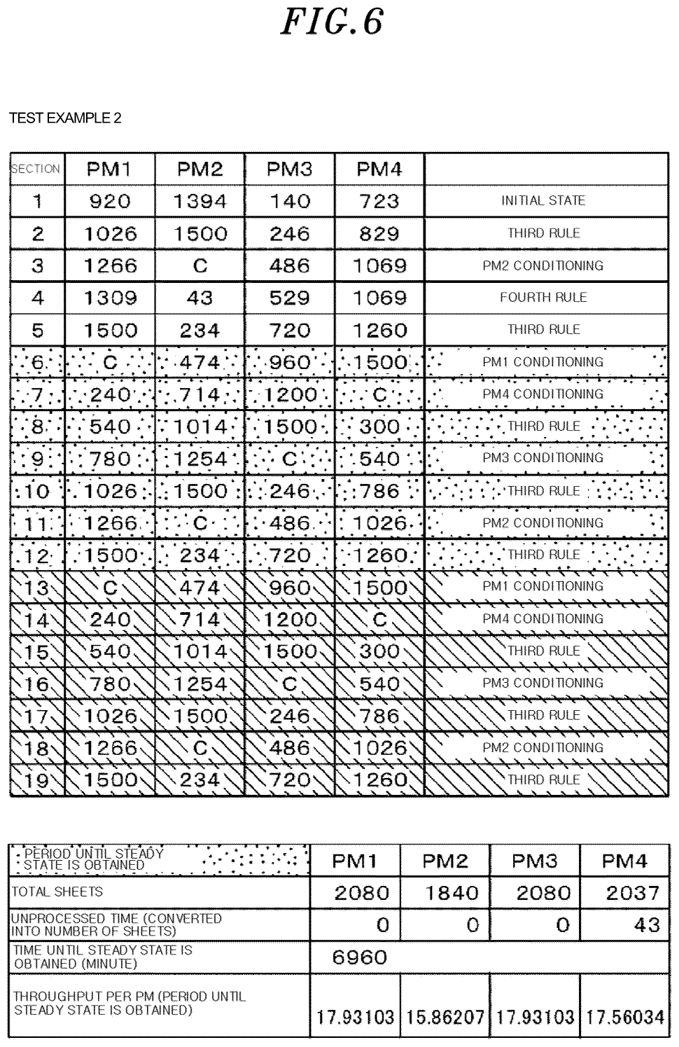

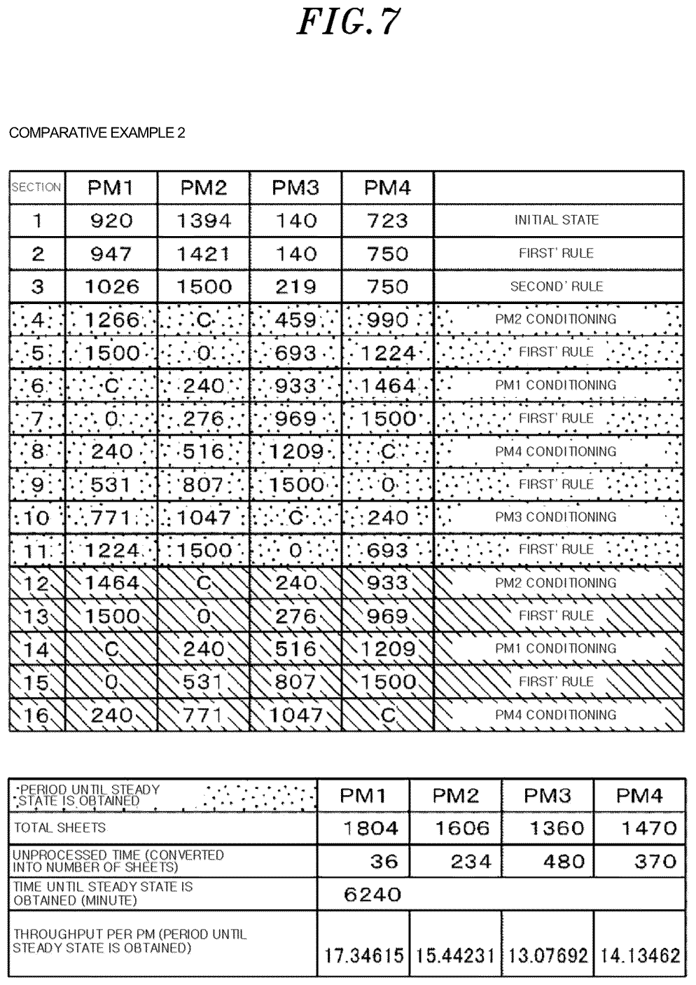

FIG. 6 shows the transfer table and the data table of test example 2, and FIG. 7 shows the transfer table and the data table of comparative example 2. In each section of test example 2, the rules to be applied are determined in the same order as that in test example 1, so that detailed description thereof will be omitted. As shown in the data table, the time required to obtain the steady state was 6960 minutes in test example 2 and 6240 minutes in comparative example 2, which was slightly longer in test example 2. However, the minimum throughput per PM until the steady state was obtained was 15.86207 in test example 2 and 13.07692 in comparative example 2, so that test example 2 was 121.3% on the assumption that comparative example 2 was 100%. The maximum throughput per PM until the steady state was obtained was 17.93103 in test example 2 and 17.34615 in comparative example 2, so that test example 2 was 103.4% on the assumption that comparative example 2 was 100%. As described above, the throughput until the steady state was obtained was higher in test example 2.

Further, as shown in the transfer table, in comparative example 2, similarly to comparative Example 1, one cycle in the steady state includes a section in which the wafer W is not transferred immediately to the PM in which the conditioning has been performed. However, such a section does not exist in test example 2. Therefore, also in the cycle in the steady state, the throughput of each PM is higher in test example 2. From the above, the processing efficiency of the apparatus is higher in test example 2.

### Test Example 3 and Comparative Example 3

In test example 3, simulation was performed under the same conditions as those in test examples 1 and 2 except that the cumulative number of processed wafers in the initial state was different from those in test examples 1 and 2. The cumulative number of processed wafers in PM1 to PM4 in the initial state of test example 3 was not 0 unlike test example 2, but test example 3 is different from test example 2 in that the difference between the maximum and the minimum was set to n×2-480 or less. Specifically, the cumulative number of processed wafers in the initial state was set to 171, 351, 135, and 71 in PM1, PM2, PM3, and PM4, respectively. In comparative example 3, simulation was performed under the same conditions as those in test example 3.

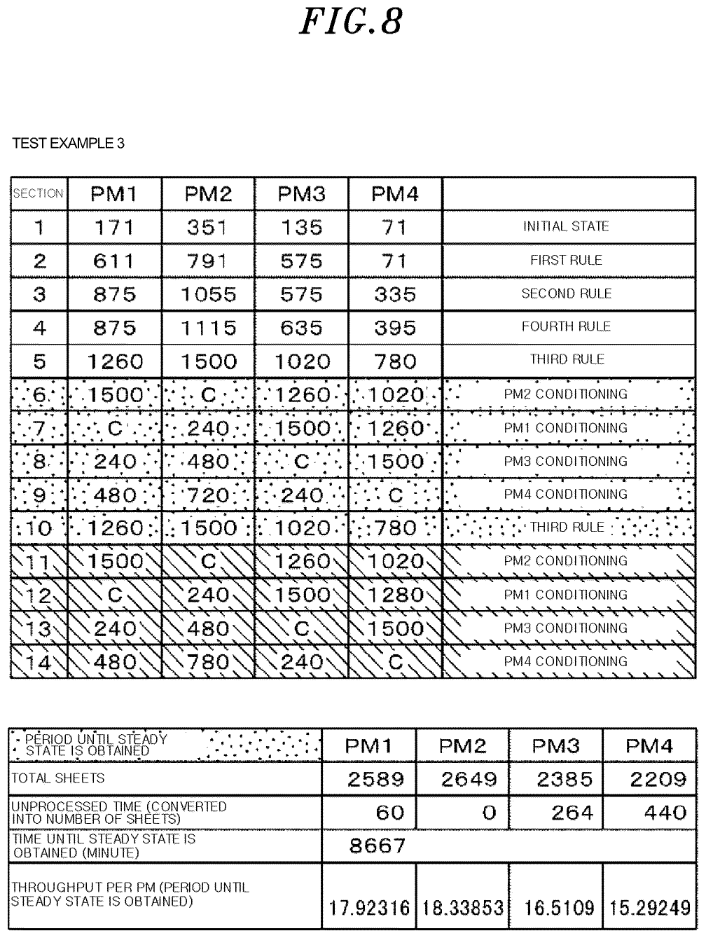

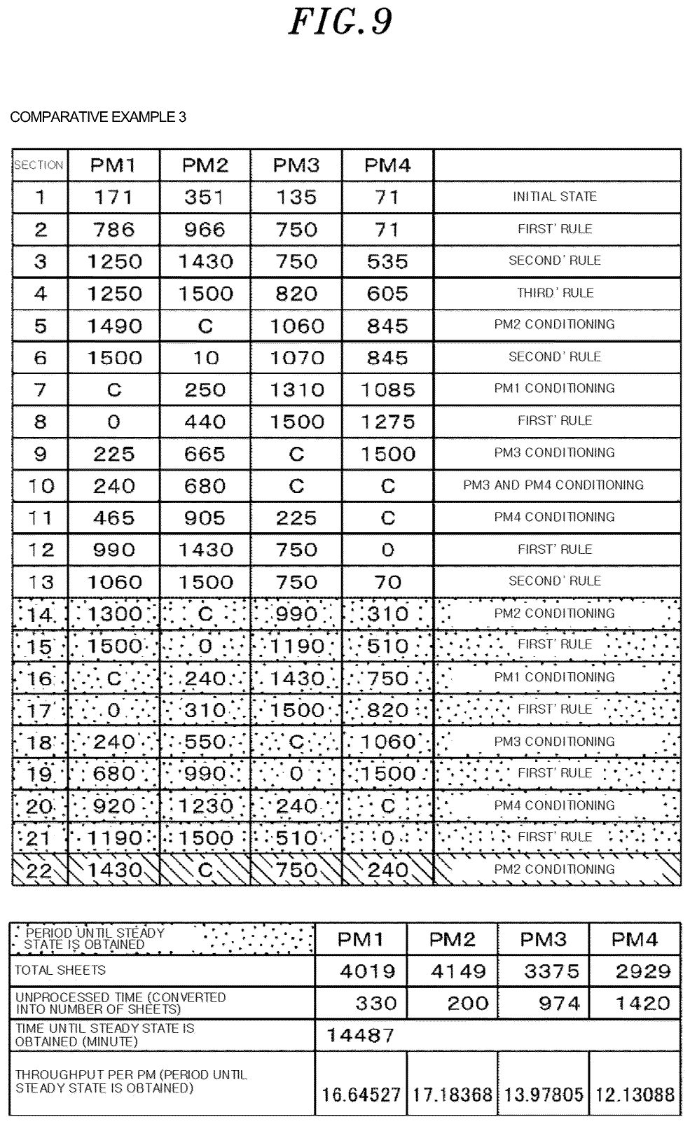

FIG. 8 shows the transfer table and the data table of test example 3, and FIG. 9 shows the transfer table and the data table of comparative example 3. Also in test example 3, the rules to be applied are determined by the same sequence as that in test example 1. Hereinafter, the sequence for determining the rules to be applied in each section up to section 5 before the steady state is obtained will be described briefly.

In the initial state of section 1, the cumulative number of processed wafers are PM2, PM1, PM3, and PM4 in descending order. Since the difference in the cumulative number of processed wafers between PM2 (first in descending order) and PM4 (fourth in descending order) is less than n×3 (=less than 720), it is determined that the first rule is applied.

In section 2, the wafers W are transferred to PM1 to PM3 according to the first rule, and the difference in the cumulative number of processed wafers between PM2 and PM4 is 720. Then, the rule to be applied is determined again. Since the difference in the cumulative number of processed wafers between PM2 and PM4 is 720, the first rule is not applied. Further, since the difference in the cumulative number of processed wafers between PM2 (first in descending order) and PM3 (third in descending order) is less than n×2 (=less than 380), it is determined that the second rule is applied.

In section 3, the wafers W are transferred to PM1, PM2, and PM4 according to the second rule, and the difference in the cumulative number of processed wafers between PM2 and PM3 is 480. Then, the rule to be applied is determined again. Since the difference in the cumulative number of processed wafers between PM2 and PM4 is 720, the first rule is not applied. Further, since the difference in the cumulative number of processed wafers between PM2 and PM3 is 480 (n×2 or more), the second rule is not applied. Further, since the difference in the cumulative number of processed wafers between PM2 (first in descending order) and PM1 (second in descending order) is not 240 or more, the third rule is not applied, and it is determined that the fourth rule is applied.

In section 4, the wafers W are transferred to PM2 to PM4 according to the fourth rule, and the difference in the cumulative number of processed wafers between PM2 and PM1 is 240. Then, the rule to be applied is determined again. Since the difference in the cumulative number of processed wafers between PM2 and PM4 is 720 (n×3 or more), the first rule is not applied. Since the difference in the cumulative number of processed wafers between PM2 and PM3 is 480 (n×2 or more), the second rule is not applied. Since the difference in the cumulative number of processed wafers between PM2 (first in descending order) and PM1 (second in descending order) is 240 or more, the third rule is determined to be applied. In section 5, the wafers W are transferred to PM1 to PM4 according to the third rule, and when the cumulative number of processed wafers in PM2 reaches 1500 that is the cumulative number of processed wafers N of the C trigger, section 5 is ended.

Also in subsequent sections in test example 3 and test examples subsequent to test example 3, the rules to be applied are determined in the same manner as that in sections 1 to 5 of test example 3 and each section of test example 1, so that the description of determination of the rules will be omitted below.

As shown in the table of each data, the time required until the steady state was obtained was 8667 minutes in test example 3 and 14487 minutes in comparative example 3, which was shorter in test example 3 and was preferable. The minimum throughput per PM until the steady state was obtained was 15.29249 in test example 3 and 12.13088 in comparative example 3, so that test example 3 was 126.1% on the assumption that comparative example 3 was 100%. The maximum throughput per PM until the steady state was obtained was 18.33853 in test example 3 and 17.18368 in comparative example 3, so that test example 3 was 106.7% on the assumption that comparative example 3 was 100%. As described above, the throughput until the steady state was obtained was higher in test example 3. In comparative example 3, similarly to comparative examples 1 and 2, the cycle in the steady state includes a section in which the wafer W is not immediately transferred to the PM in which the conditioning has been performed. However, such a section does not exist in test example 3. Therefore, also in one cycle in the steady state, the throughput of each PM is higher in test example 3. From the above, the processing efficiency of the apparatus is higher in test example 3.

### Test Example 4 and Comparative Example 4

In test example 4, simulation was performed under the same conditions as those in test examples 1 to 3 except that the cumulative number of processed wafers in the initial state was different from those in test examples 1 to 3. The cumulative number of processed wafers in PM1 to PM4 in the initial state was not 0 unlike test examples 2 and 3, but test example 4 is different from test examples 2 and 3 in that the difference between the maximum and the minimum was set to n×3=720 or less, and the difference between the first and the second in descending order was set to n(=240) or more. Specifically, in the initial state, the cumulative number of processed wafers was set to 706, 461, 205, and 81 in PM1, PM2, PM3, and PM4, respectively. In comparative example 4, simulation was performed under the same conditions as those in test example 4.

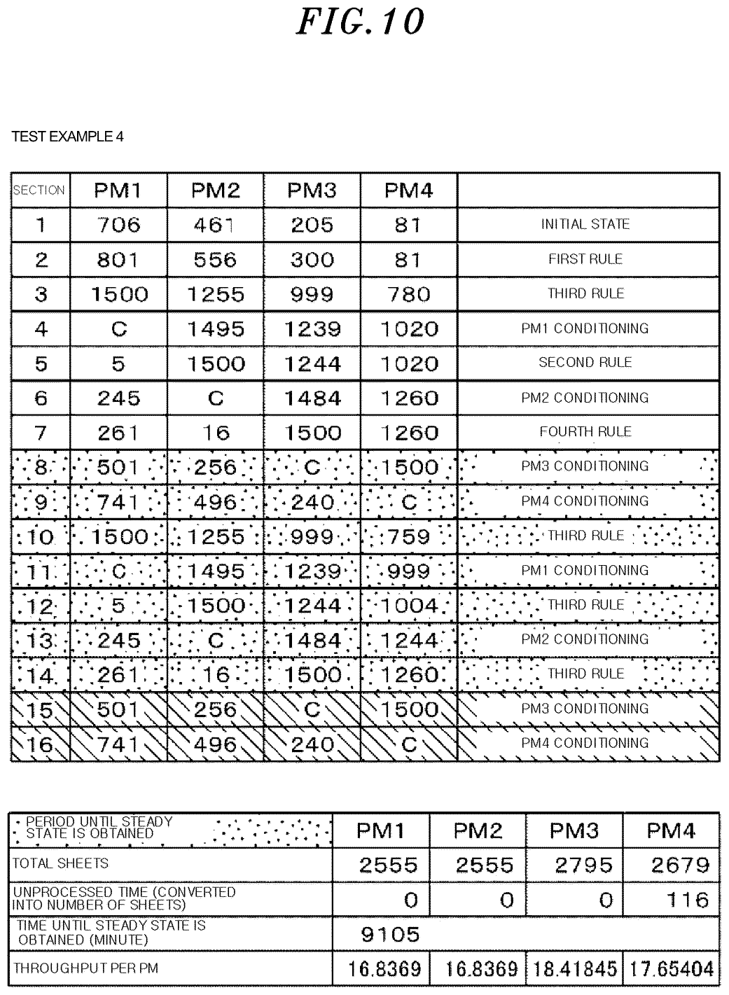

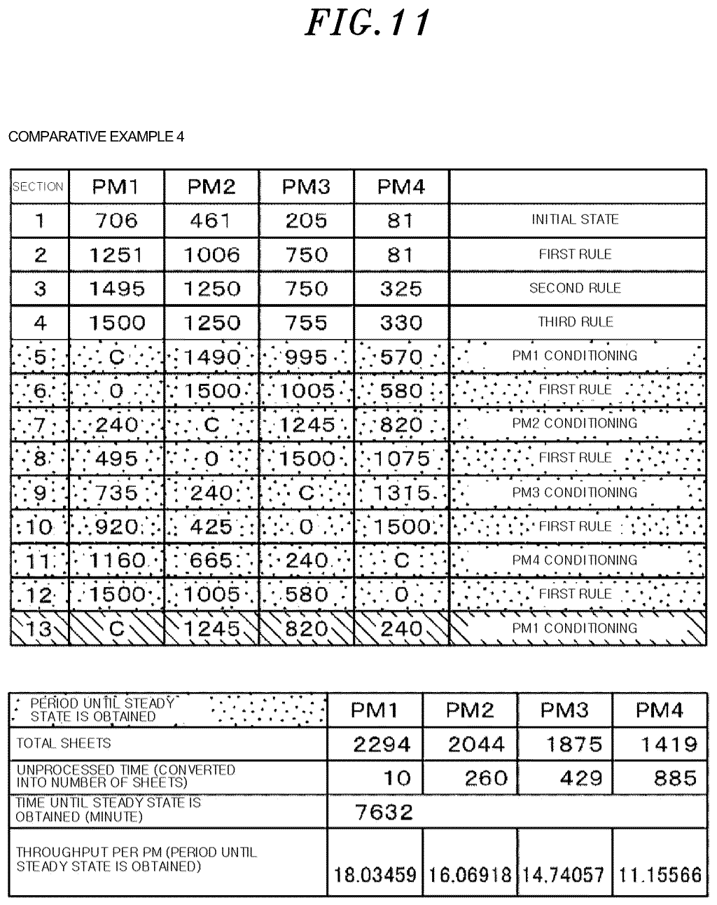

FIG. 10 shows the transfer table and the data table of test example 4, and FIG. 11 shows the transfer table and the data table of comparative example 4. As shown in the data tables, the time required to obtain the steady state was 9105 minutes in test example 4 and 7632 minutes in comparative example 4, which was shorter in comparative example 4. However, the minimum throughput per PM until the steady state was obtained was 16.8369 in test example 4 and 11.15566 in comparative example 4, so that test example 4 was 150.9% on the assumption that comparative example 4 was 100%. The maximum throughput per PM until the steady state was obtained was 18.41845 in test example 4 and 18.03459 in comparative example 4, so that test example 4 was 102.1% on the assumption that comparative example 4 was 100%. As described above, the throughput until the steady state was obtained was higher in test example 4. Similarly to comparative examples 1 to 3, in comparative example 4, one cycle in the steady state includes a section in which the wafer W is not immediately transferred to the PM in which the conditioning has been performed. However, such a section does not exist in test example 4. Hence, the throughput of each PM was higher in test example 4 also in the cycle in the steady state. From the above, the processing efficiency of the apparatus was higher in test example 4.

### Test Example 5 and Comparative Example 5

In test example 5, simulation was performed under the same conditions as those in test example 1 except that the cumulative number of processed wafers N of the C trigger was set to 1440. Therefore, in test example 5, the processing time of (the cumulative number of processed wafers N of the C trigger/3) wafers W is 1440 minutes, and the difference between the conditioning execution time and the processing time of (the cumulative number of processed wafers N of the C trigger/3) wafers W is smaller than that in test example 1. Due to the small difference, although the relationship of inequality (1) (the conditioning execution time the processing module PM<the processing time of (the cumulative number of processed wafers N of the C trigger/3) sheets) is satisfied, the value of the right side of inequality (1) is twice the value of the left side of inequality (1). In comparative example 5, simulation was performed under the same conditions as those in test example 5.

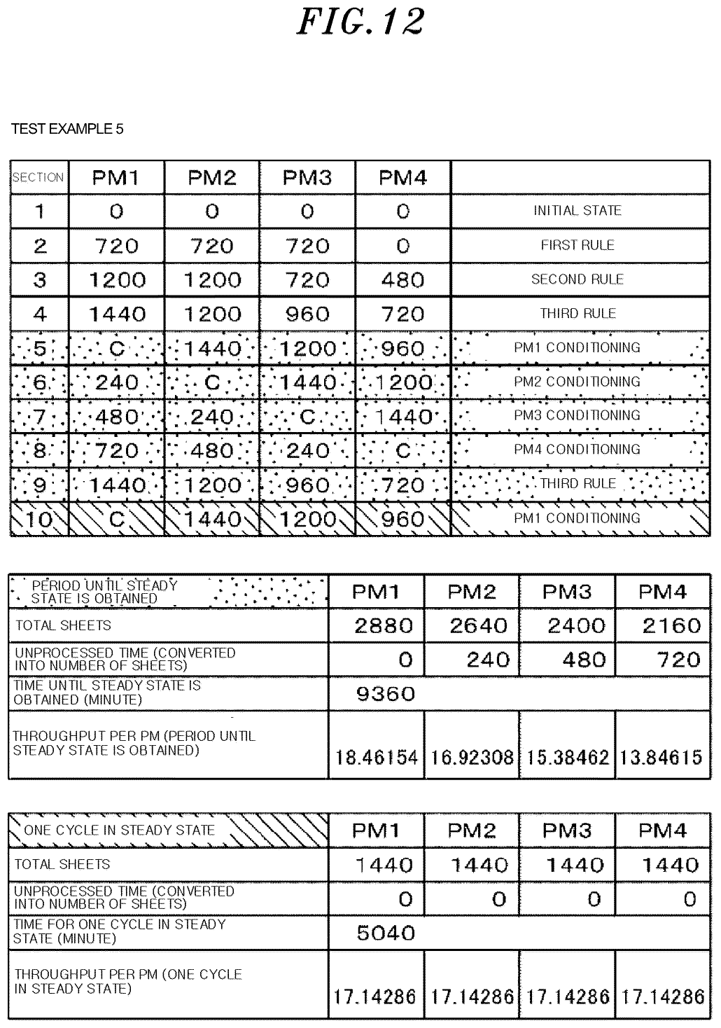

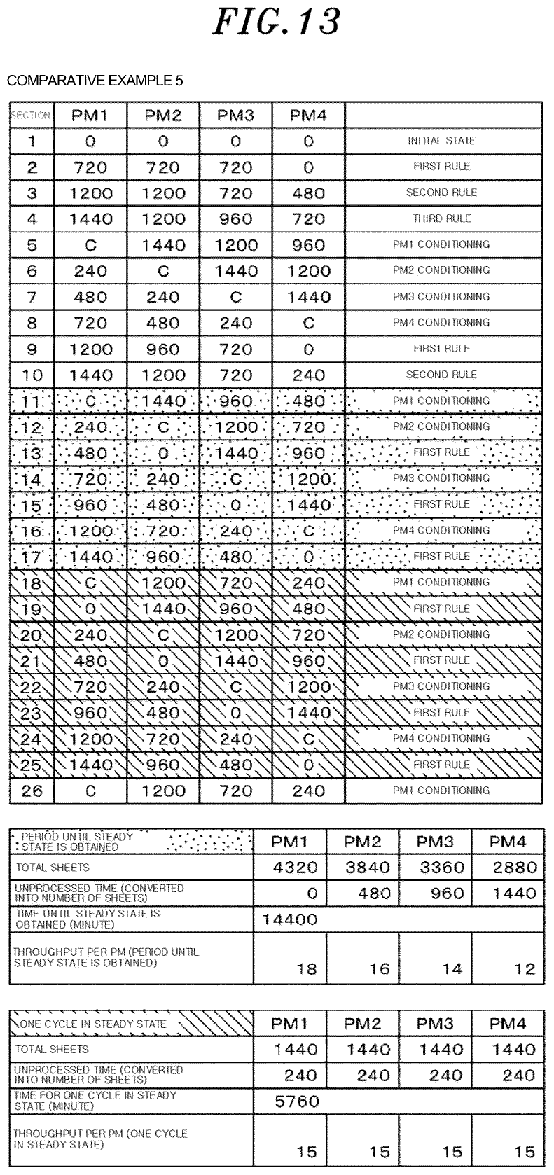

FIG. 12 shows the transfer table and the data table of test example 5, and FIG. 13 shows the transfer table and THE data table of comparative example 5. As shown in the data tables, the time until the steady state was obtained was 9630 minutes in test example 5 and 14400 minutes in comparative example 5, which was shorter in test example 5 and was desirable. The minimum throughput per PM until the steady state was obtained was 13.84615 in test example 5 and 12 in comparative example 5, so that test example 5 was 115.4% on the assumption that comparative example 5 was 100%. Further, the maximum throughput per PM until the steady state was obtained was 18.46154 in test example 5 and 18 in comparative Example 5, so that test example 5 was 102.6% on the assumption that comparative example 5 was 100%. As described above, the throughput until the steady state was obtained was higher in test example 5.

Further, the throughput per PM in one cycle in the steady state was 17.14286 in test example 5 and 15 in comparative example 5, so that test example was 114.3% on the assumption that comparative example 5 was 100%. As described above, the throughput of each PM was higher in test example 5 in both the period required until the steady state was obtained and the cycle in the steady state. As described above, the throughput of each PM was higher in test example 5 both in the period required until the steady state was obtained and in the cycle in the steady state. From the above, it was confirmed that the processing efficiency of the apparatus was higher in test example 5.

### Test Example 6 and Comparative Example 6

In test example 6, simulation was performed under the same conditions as those in test example 1 except that the cumulative number of processed wafers N of the C trigger was set to 1080. Therefore, in test example 6, the processing time of (the cumulative number of processed wafers N of the C trigger/3) wafers W was 1080 minutes, and the difference between the conditioning execution time and the processing time of (the cumulative number of processed wafers N of the C trigger/3) wafers W was smaller than those in test examples 1 and 5. Although the relationship of inequality (1) (the conditioning execution time of the processing module PM<the processing time of (the cumulative number of processed wafers N of the C trigger/3) sheets) is satisfied due to the small difference, the value of the right side of inequality (1) is 1.5 times the value of the left side of inequality (1). In comparative example 6, simulation was performed under the same conditions as those in test example 6.

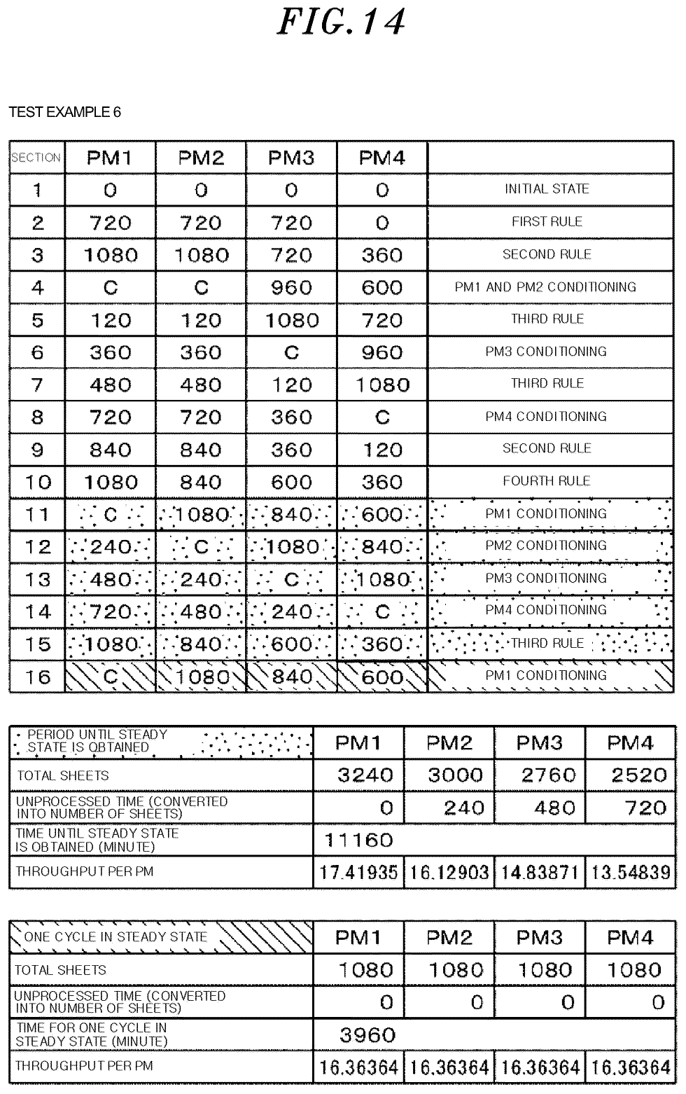

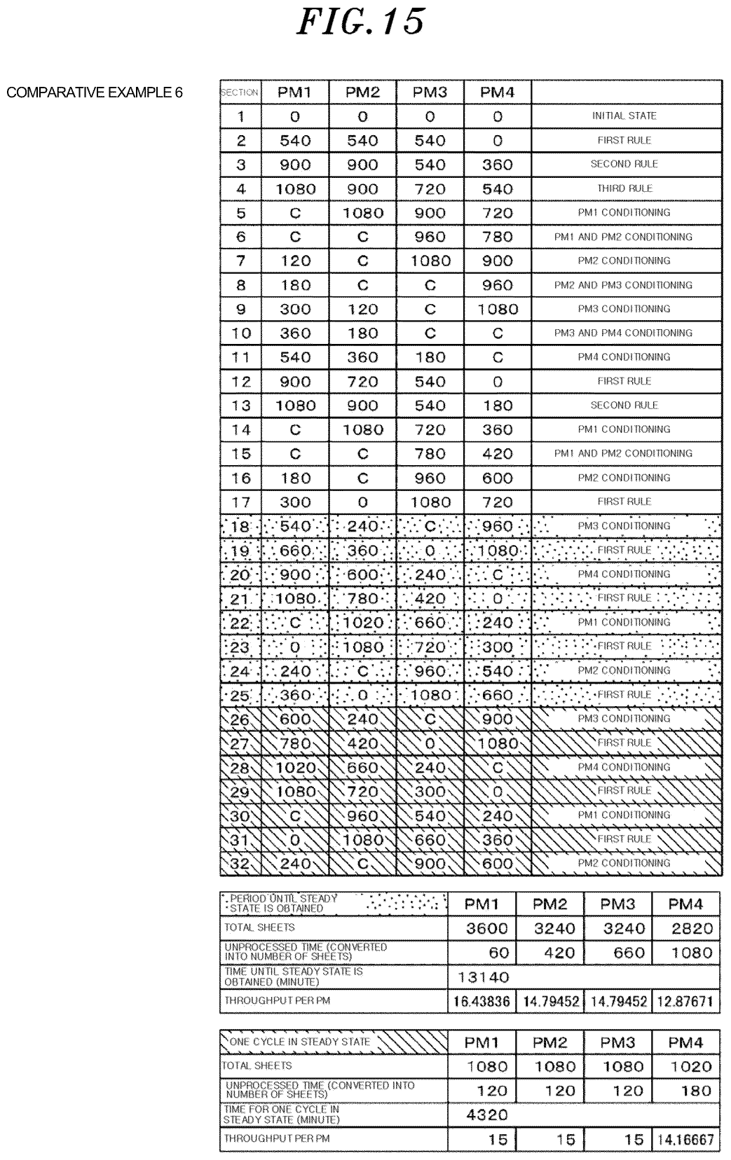

FIG. 14 shows the transfer table and the data table of test example 6, and FIG. 15 shows the transfer table and the data table of comparative example 6. As shown in the data tables, the time required until the steady state was obtained was 11160 minutes in test example 6 and 13140 minutes in comparative example 6, which was shorter in test example 6. The minimum value of throughput per PM until the steady state was obtained was 13.54839 in test example 6 and 12.87671 in comparative example 6, so that test example was 105.2% on the assumption that comparative example 6 was 100%. Further, the maximum throughput per PM until the steady state was obtained was 17.41935 in test example 6 and 16.43836 in comparative example 6, so that test example 6 was 109.1% on the assumption that comparative example 6 was 100%. As described above, the throughput until the steady state was obtained was higher in test example 6. Further, the throughput per PM in one cycle in the steady state was 16.36364 in test example 6 and 15 in comparative example 6, so that test example 6 was 109.1% on the assumption that comparative example 6 was 100%. As described above, the throughput of each PM was higher in test example 6 in both the period required until the steady state was obtained and the cycle in the steady state. From the above, it was confirmed that the processing efficiency of the apparatus was higher in test example 6.

### Test Example 7 and Comparative Example 7

In test example 7, simulation was performed under the same conditions as those in test example 1 except that the cumulative number of processed wafers N of the C trigger was set to 720. Therefore, in test example 7, the processing time of (the cumulative number of processed wafers N of the C trigger/3) wafers W was 720 minutes, and the relationship of inequality (1) was not satisfied, whereas the relationship of Eq. (1) 1 was satisfied. In comparative example 7, simulation was performed under the same conditions as those in test example 7.

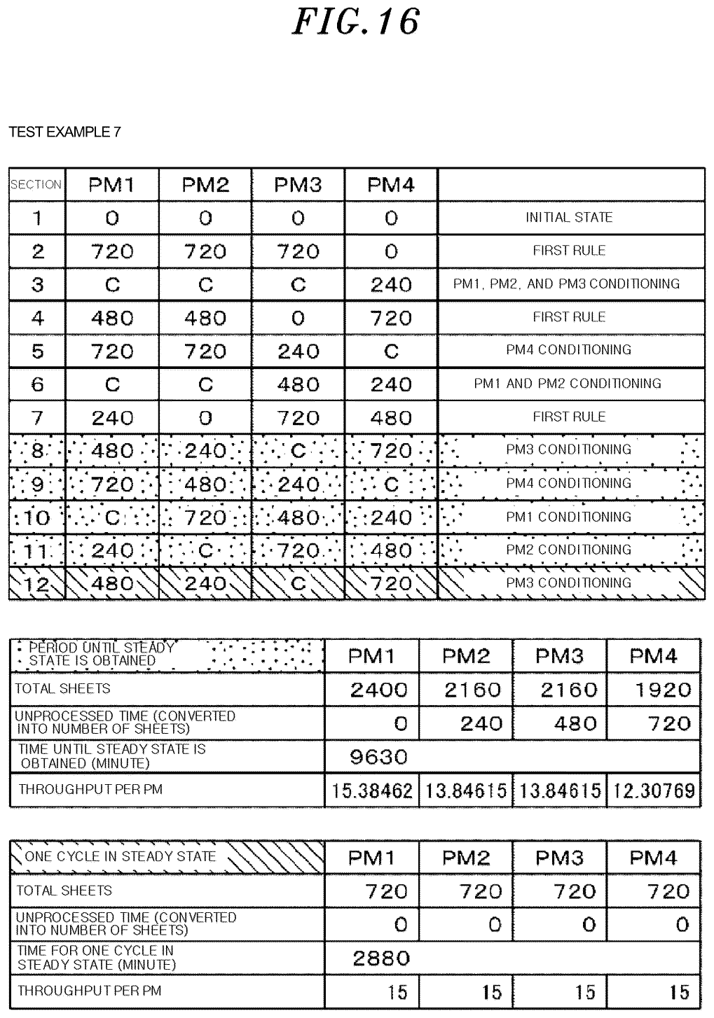

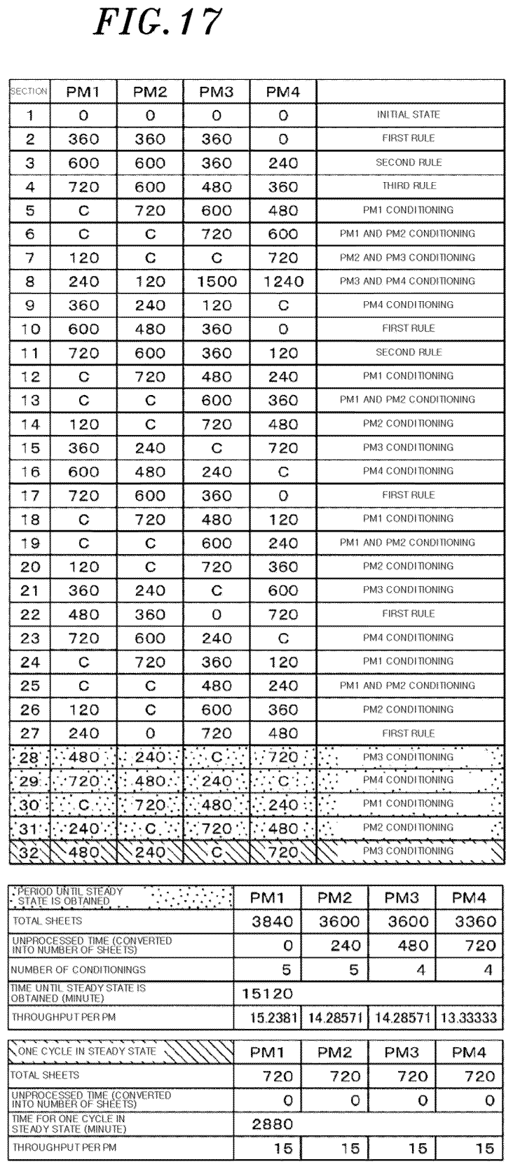

FIG. 16 shows the transfer table and the data table of test example 7, and FIG. 17 shows the transfer table and the data table of comparative example 7. As shown in the data tables, the time required until the steady state was obtained was 9360 minutes in test example 7 and 15120 minutes in comparative example 7, which was shorter in test example 7. Further, the time for one cycle in the steady state was 2880 minutes in each of test example 7 and comparative example 7.

The minimum throughput per PM until the steady state was obtained was 12.30769 in test example 7 and 13.33333 in comparative example 7, so that test example 7 was 92.3% on the assumption that comparative example was 100%. The maximum throughput per PM until the steady state was obtained was 15.38462 in test example 7 and 15.2381 in comparative example 7, so that test example 7 was 101.1% on the assumption that comparative example 7 was 100%. The throughput per PM in one cycle in the steady state was 15 in both test example 7 and comparative example 7, so that there was no difference.

As described above, there is no difference in throughput between test example 7 and comparative example 7 in the steady state, and the minimum throughput per PM in the period until the steady state was obtained was larger in comparative example 7. Since, however, the steady state is quickly obtained in test example 7, it was confirmed that the processing efficiency of the apparatus was higher in test example 7 than comparative example 7.

### Test Example 8

In test example 8, simulation was performed under the same conditions as those in test example 1 except that the cumulative number of processed wafers N of the C trigger N was set to 480. Therefore, in test example 8, the processing time of (the cumulative number of processed wafers N of the C trigger/3) wafers W is 480 minutes, which is ⅔ of the conditioning execution time. Accordingly, the conditioning execution time of the processing module PM is greater than the processing time of (the cumulative number of processed wafers N of the C trigger/3) wafers), and the relationship of inequality (1) and Eq. (1) are not satisfied. In comparative example 8, simulation was performed under the same conditions as those in test example 8.

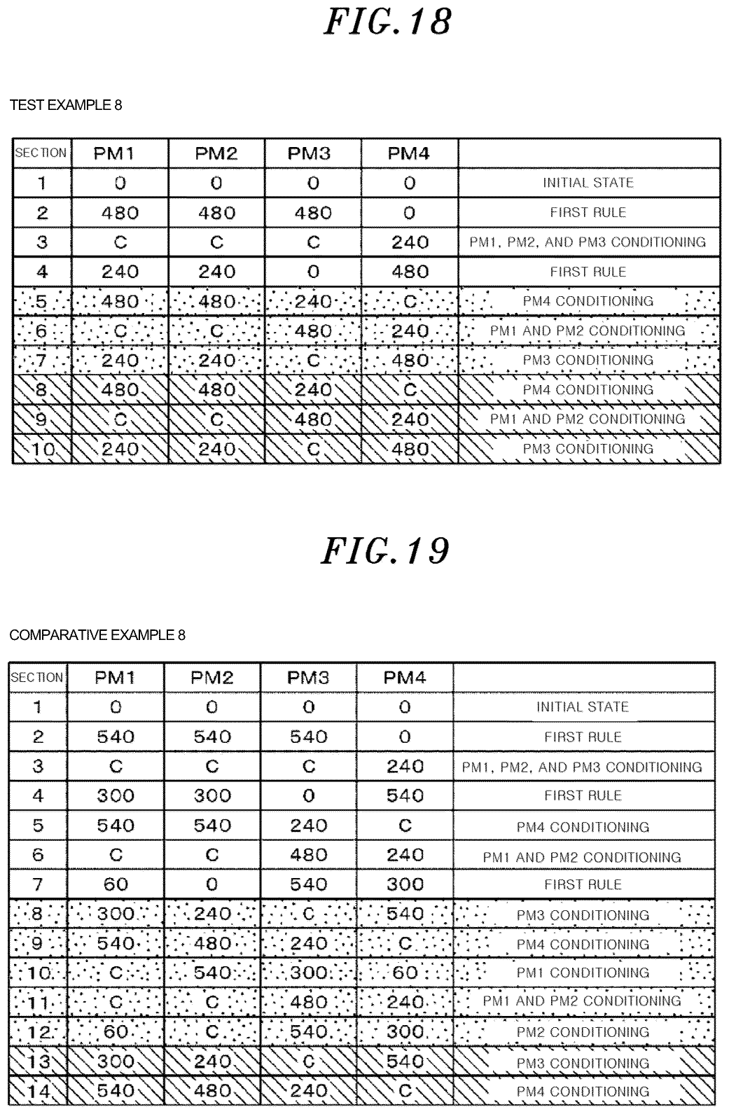

FIGS. 18 and 19 show the transfer tables of test example 8 and comparative example 8, respectively. As shown in the transfer tables, similarly to comparative example 1, in comparative example 8, there is a section in which the wafer W is not immediately transferred to the PM in which the conditioning has been performed. However, such a section does not exist in test example 8. Therefore, the processing efficiency of the apparatus was higher in test example 8 than in comparative example 8. However, as shown in the transfer tables, unlike the embodiments described so far, in test example 8, the conditionings of PM1 and PM2 are performed in the same section in the steady state.

Although the transfer table is omitted, in test example 9, the same simulation as that in test example 8 was performed by setting the cumulative number of processed wafers N of the C trigger to 540. Therefore, in test example 9, the processing time of (the cumulative number of processed wafers N of the C trigger/3) wafers W was 540 minutes, which was ¾ of the conditioning execution time. Hence, similarly to test example 8, the relationships of inequality (1) and Eq. (1) are not satisfied. Similarly to test example 8, in test example 9, the conditioning was performed in two PMs in the same section in the steady state.

### (Summary of Simulation Results)

The processing efficiency of the apparatus can be increased by forming a state in which the sections in which the conditionings of PMs are performed are shifted so that the conditioning is performed in only one PM and the wafers W are processed in the other PMs. Such a steady state was formed in test examples 1 to 7 among test examples 1 to 9. Therefore, it was confirmed that it is preferable to apply the transfer of test example when the condition set in test examples 1 to 7, i.e., the conditioning execution time of the processing module PM≤(the cumulative number of processed wafers N of the C trigger/(the number of processing modules PM−1)) wafers, is satisfied.

When test examples 1 to 6 in which the relationship of inequality (1) is satisfied are compared with test example 7 in which the relationship of Eq. (1) is satisfied, both the minimum and maximum values of the throughput per PM until the steady state is obtained, and the throughput per PM in one cycle in the steady state are larger in test examples 1 to 6 than in comparative example. Therefore, it was confirmed that it is more preferable to apply the transfer of test example when the relationship of inequality (1) is satisfied than when the relationship of Eq. (1) is satisfied.

### (Application to Other Device Configurations)

The determination flow shown in FIG. 3 for determining the rules to be applied can be performed by executing the following steps T1 to T3.

The difference between the cumulative number of processed wafers of the PM that is first in the cumulative number of processed wafers in descending order and the cumulative number of processed wafers of a PM selected among the PMs other than the first PM is compared with n×(the order of the cumulative number of processed wafers in descending order of the selected PM−1) (step T1).

According to the comparison result of step T1, the PM as a transfer destination is determined, or the PM that is one rank higher in descending order of the cumulative number of processed wafers than the PM selected in immediately previously executed step T1 is selected again (step T2).

If a PM is selected again in step T2, step T1 is executed again (step T3).
The selected PM being selected initially is the one with the lowest rank in descending order of the cumulative number of processed wafers.

The determination of the PM as a transfer destination in step T2 corresponds to one of the following case 1 and case 2.

### <Case 1>

If the difference between the cumulative number of processed wafers of the PM that is first in the cumulative number of processed wafers in descending order and the cumulative number of processed wafers of the selected PM is less than n×(the cumulative number of processed wafers of the selected PM in descending order−1) according to the result of comparison of step T1, PMs other than the selected PM are determined as transfer destinations.

### <Case 2>

If the result of comparison of step T2 shows that the difference between the cumulative number of processed wafers of the PM that is first in the cumulative number of processed wafers in descending order and the cumulative number of processed wafers of the selected PM is more than n and the selected PM is the PM that is second in the cumulative number of processed wafers in descending order, all PMs are determined as transfer destinations.

The correspondence between steps T1 to T3 and rules 1 to 4 will be described. Unless otherwise specified, the cumulative number of processed wafers in the description is counted in the descending order.

Since the substrate processing apparatus 1 includes four PMs, the PM that is the lowest rank in descending order of the cumulative number of processed wafers (i.e., the PM having the smallest cumulative number of processed wafers, which is the PM that is last in descending order) is the fourth PM. This PM is set to the selected PM being selected initially. Then, the difference in the cumulative number of processed wafers between the PM that is first in the cumulative number of processed wafers and the PM that is fourth in the cumulative number of processed wafers in step T1 is calculated. Then, the calculated difference in the cumulative number of processed wafers is compared with n×(“4” that is the order of the selected PM−1) (step T1). If the comparison result shows that the difference between the cumulative number of processed wafers of the PM that is first in the cumulative number of processed wafers and the cumulative number of processed wafers of the selected PM is less than n×(“4” that is the order of the cumulative number of processed wafers of the selected PM−1), the PMs that are first to third in the cumulative number of processed wafers other than the selected PM are determined as transfer destinations (step T2). Therefore, the first execution of steps T1 and T2 corresponds to the execution of the execution of the first rule.

If the result of comparison shows that the difference is not less than n×(“4”-1), the PM selected in previous step T1 is the fourth PM, so that the third PM that is lower by one in descending order of the cumulative number of processed wafers is selected again (step T2), and step T1 is performed again (step T3).

Therefore, in the second execution of step T1, the difference in the number of sheets between the PM that is first in the cumulative number of processed wafers and the PM that is third in the cumulative number of processed wafers is calculated, and is compared with n×(“3” that is the order of the selected PM−1). Therefore, the second execution of step T1 and the execution of step T2 after the second execution of step T1 correspond to the execution of the second rule.

By repeating steps T1 to T3 without determining the PM as a transfer destination, the PM that is second in the cumulative number of processed wafers is selected. The difference in the number of sheets between the PM that is first in the cumulative number of processed wafers and the PM that is second in the cumulative number of processed wafers is compared with n×(“2” that is the order of the selected PM−1) (step T1). As a result of the comparison, if the difference between the cumulative number of processed wafers of PM that is first in the cumulative number of processed wafers and the cumulative number of processed wafers of the selected PM is n or more, all PMs are determined as transfer destinations. If it is less than n, the PMs that are first, third, and fourth in the cumulative number of processed wafers other than the selected PM that is second in the cumulative number of processed wafers are determined as transfer destinations. This corresponds to the execution of the third and fourth rules.

The number of processing modules PM included in the substrate processing apparatus 1 is not limited to four, and may be three or may be any number greater than four. The PM as a transfer destination may be determined according to steps T1 to T3. In the case where there are three PMs, steps T1 to T3 may be performed such that the PM that is last in the cumulative number of processed wafers in descending order among the three PMs is initially selected. In the case where there are five PMs, steps T1 to T3 may be performed such that the PM that is last in the cumulative number of processed wafers in descending order among the five PMs is initially selected.

Although film formation, cleaning, and pre-coating have been described as plasma processing, all or some of them may be performed without turning a gas into plasma. Further, the film formation and the pre-coating for the wafer W may be performed by atomic layer deposition (ALD).

The processing module PM does not necessarily perform film formation, and may perform etching or annealing. Further, the conditioning is determined arbitrarily depending on the configuration of the processing module, and may include only cleaning without including pre-coating, for example. Further, the processing module PM does not necessarily perform processing in a vacuum atmosphere, and may process a substrate in an atmospheric atmosphere. Therefore, a substrate transfer path between the transfer chamber 14 and the processing module PM may not include a vacuum atmosphere, and may include only an atmospheric pressure atmosphere. Further, the substrate is not limited to the wafer W, and may be, e.g., a square substrate for manufacturing a flat panel or an organic EL display.

In the above example, the timing of determining the rule to be applied is synchronized with the switching the lot of the wafer W. However, it is not necessarily synchronized with the switching of the lot. For example, the determination may be performed whenever any Y wafers W are taken out from the transfer chamber 14. The conditioning may also be started, regardless of the timing of switching the lot, when the cumulative number of processed wafers has reached the cumulative number of processed wafers N of the C trigger, as in the simulation.

In the above description, the PM to which the wafer W is transferred is determined based on the cumulative number of processed wafers of wafers W in each PM. However, when each PM performs film formation as in the substrate processing apparatus 1, the transfer destination of the wafer W may be determined based on a cumulative film thickness instead of the cumulative number of processed wafers. The film thickness of the film formed on the wafer W and each part of the PM by performing film formation once is set to A nm. In other words, in the processing chamber 21 of the PM, the film thickness increases by A nm whenever the film formation is performed once. A is a real number. The cumulative film thickness of the C trigger is set instead of the cumulative number of processed wafers N of the C trigger, and the conditioning is controlled to be performed in the PM when the cumulative film thickness (=A nm×the number of times of execution of film formation) after conditioning reaches the cumulative film thickness of the C trigger. By replacing the cumulative number of processed wafers and n in the above description of the transfer control and the determination for each PM with the cumulative film thickness and n×A, respectively, the PM to which the wafer W is transferred can be determined in the same manner as in the case of determining the transfer destination based on the cumulative number of processed wafers. Specifically, the first to fourth rules are replaced with the following rules based on the cumulative film thickness, and the determination of the transfer destination and the transfer control are performed according to the replaced rules.

### First Rule

If the difference in the cumulative film thickness between the processing module PM that is first in the cumulative film thickness in descending order and the processing module PM that is fourth in the cumulative film thickness in descending order is less than (A×n×3) nm, the processing modules PMs that are first to third in the cumulative film thicknesses in descending order are used for processing.

### Second Rule

If the difference in the cumulative film thickness between the processing module PM that is first in the cumulative film thickness in descending order and the processing module PM that is third in the cumulative film thickness in descending order is less than (A×n×2) nm, the processing modules PMs that are first, second and fourth in the cumulative film thicknesses in descending order are used for processing.

### Third Rule

If the difference in the cumulative film thickness between the processing module PM that is first in the cumulative film thickness in descending order and the processing module PM that is second in the cumulative film thickness in descending order is (A×n) nm or more, all the processing modules PMs are used for processing.

### Fourth Rule

If none of the first, second, and third rules are applied, the processing modules PMs that are first, third, and fourth in the cumulative film thickness in descending order are used for processing.

In the case of using the first to fourth rules based on the cumulative film thickness, the transfer control is performed based on the first to fourth rules such that the difference in the cumulative film thickness between the PMs becomes A×n (unit: nm) or more. Further, in the case of using the first to fourth rules based on the cumulative number of processed wafers, the difference of n or more (i.e., 1×n or more) in the cumulative number of processed wafers is formed between the PMs. Therefore, both when the first to fourth rules are based on the cumulative film thickness and when the first to fourth rules are based on the cumulative number of processed wafers, the transfer control is performed such that the difference in the cumulative film thickness or the cumulative number of processed wafers formed between the PMs becomes greater than or equal to a value determined by n. More specifically, the transfer control is performed such that the difference becomes greater than or equal to a value obtained by multiplying n by a predetermined real number. In the case of using the cumulative film thickness, the predetermined real number is A, and in the case of using the cumulative number of processed wafers, the predetermined real number is 1.

As described above, the transfer destination of the wafer W can be determined based on a parameter corresponding to the cumulative number of processed wafers of wafers W, such as the cumulative number of processed wafers or the cumulative film thickness, which is counted to be accumulated whenever the wafer W is processed and is reset to 0 by the execution of conditioning.

Further, steps T1 to T3 in which the first to fourth rules based on the cumulative number of processed wafers are modified can be executed by replacing the cumulative number of processed wafers with the cumulative film thickness and replacing n with A×n. In other words, in a state where no conditioning is performed in any of the PMs, the difference between the cumulative film thickness of the PM that is first in the cumulative film thickness in descending order and the cumulative film thickness of a PM selected among the other PMs other than the first PM is compared with A×n×(the order of the cumulative film thickness in descending order of the selected PM−1). According to the comparison result, the PM as a transfer destination is determined, or the comparison is performed by selecting again a PM that is lower by 1 in descending order of the cumulative film thickness than the previously selected PM, so that the PM that is the lowest rank in descending order of the cumulative film thickness is set to the initially selected PM.

It should be noted that the embodiments of the present disclosure are illustrative in all respects and are not restrictive. The above-described embodiments may be omitted, replaced, changed and/or combined in various forms without departing from the scope of the appended claims and the gist thereof.

### DESCRIPTION OF REFERENCE NUMERALS

PM1 to PM4: processing module
W: wafer
12, 18: transfer mechanism
40: controller

1. A substrate processing apparatus comprising:
a plurality of processing modules, each of which includes a processing chamber for storing a substrate and performing same processing and each of which performs conditioning in the processing chamber;
a transfer mechanism configured to transfer the substrate to each of the plurality of processing modules; and
a controller configured to determine a processing module to which the substrate is transferred among the plurality of processing modules based on a parameter corresponding to a cumulative number of processed substrates after the conditioning with respect to each of the plurality of processing modules, an execution time of the conditioning, and a processing time per substrate of the plurality of processing modules.

2. The substrate processing apparatus of claim 1, wherein when an integer obtained by dividing the execution time of the conditioning by the processing time per substrate and rounding off decimal parts other than 0 is set to n,
the substrate is transferred to each processing module such that a difference in the parameter corresponding to the cumulative number of processed substrates after the conditioning between the plurality of processing modules becomes greater than or equal to a value determined by n.

3. The substrate processing apparatus of claim 1, wherein the controller sets all the plurality of processing modules as a substrate transfer destination in a state where the conditioning is not performed in any of the processing modules and a difference in the parameter corresponding to the cumulative number of processed substrates after the conditioning between the plurality of processing modules is greater than or equal to the value determined by n.

4. The substrate processing apparatus of claim 3, wherein a cycle in which the conditioning is sequentially performed in the plurality of processing modules is repeated, and
when a section in which no conditioning is performed in any of the plurality of processing modules is formed during the cycle, all the plurality of processing modules serve as the substrate transfer destination in the section.

5. The substrate processing apparatus of claim 4, wherein the parameter corresponding to the cumulative number of processed substrates is the cumulative number of processed substrates, and the value determined by n is n, and
in a case of determining a processing module as a substrate transfer destination, in a state where the conditioning is not performed in any of the plurality of processing modules, the controller compares a difference between a cumulative number of processed substrates of a processing module that is first in the cumulative number of processed substrates in descending order and a cumulative number of processed substrates of a processing module selected among the plurality of processing modules other than the first processing module with n×(the order of the cumulative number of processed substrates in descending order of the selected processing module−1), determines the processing module as a transfer destination or performs the comparison by selecting again a processing module that is one rank higher in descending order of the cumulative number of processed substrates than a previously selected processing module according to the comparison result, and sets the processing module that is last in descending order of the cumulative number of processed substrates as an initially selected processing module.

6. The substrate processing apparatus of claim 5, wherein the plurality of processing modules are four processing modules, and
the controller determines whether or not a following First to Fourth rules are applicable in ascending order, and determines the processing module as the substrate transfer destination according to the rule that is determined to be applicable.
First rule: if the difference in the cumulative number of processed substrates between a processing module that is first in the cumulative number of processed substrates in descending order and a processing module that is fourth in the cumulative number of processed substrates in descending order is less than (n×3), the plurality of processing modules that are first to third in the cumulative number of processed substrates in descending order are used for processing;
Second rule: if the difference in the cumulative number of processed substrates between a processing module that is first in the cumulative number of processed substrates in descending order and a processing module that is third in the cumulative number of processed substrates in descending order is less than (n×2), the plurality of processing modules that are first, second, and fourth in the cumulative number of processed substrates in descending order are used for processing;
Third rule: if the difference in the cumulative number of processed substrates between a processing module that is first in the cumulative number of processed substrates in descending order and a processing module that is second in the cumulative number of processed substrates in descending order is greater than or equal to (n), all processing modules are used for processing; and
Fourth rule: if none of the first, second, and third rules are applied, the plurality of processing modules that are first, third, and fourth in the cumulative number of processed substrates in descending order are used for processing.

7. The substrate processing apparatus of claim 4, wherein the processing modules performing film formation on the substrate,
the parameter corresponding to the cumulative number of processed substrates is a cumulative film thickness,
the value determined by n is a thickness of a film formed on the substrate×n, and
in the case of determining a processing module as a substrate transfer destination, in a state where the conditioning is not performed in any of the plurality of processing modules, the controller compares a difference between a cumulative film thickness of a processing module that is first the cumulative film thickness in descending order and a cumulative film thickness of a processing module selected among the plurality of processing modules other than the first processing module with the thickness of the film formed on the substrate×n×(the order of the cumulative film thickness in descending order of the selected processing module−1), determines the processing module as the transfer destination or performs the comparison by selecting again a processing module that is lower by 1 in descending order of the cumulative film thickness than the previously selected processing module according to the comparison result, and sets the processing module that is the last in descending order of the cumulative film thickness as the initially selected processing module.

8. The substrate processing apparatus of claim 5, wherein, when a set value for the cumulative number of processed substrates after an end of previous conditioning until next conditioning is performed is set to N (N being a positive integer),
the execution time of the conditioning is less than the processing time of (N/(the number of the processing modules−1)) substrates.

9. A substrate processing method comprising:
storing a substrate in a processing chamber of each of a plurality of processing modules and performing same processing on the substrate;
performing conditioning in the processing chamber;
transferring the substrate to said each of the plurality of processing modules by a transfer mechanism; and
determining a processing module to which the substrate is transferred among the plurality of processing modules based on a parameter corresponding to a cumulative number of processed substrates after the conditioning for each of the processing modules, an execution time of the conditioning, and a processing time per substrate in the processing modules.
